(19) United States
(12) Patent Application Publication
(10) Pub. No.: US 2004/0146800 A1
(43) Pub. Date: Jul. 29, 2004

(54) Planographic printing plate precursor

(75) Inventors: Kotaro Watanabe, Shizuoka-ken (JP); Kaoru Iwato, Shizuoka-ken (JP); IKuo Kawauchi, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/759,199

(22) Filed: Jan. 20, 2004

(30) Foreign Application Priority Data
Jan. 20, 2003 (JP) 2003-11024

(51) Int. Cl. G03F 7/021; G03F 7/30; G03F 7/004; G03F 7/039

(52) U.S. Cl. 430/160; 430/175; 430/176; 430/270.1; 430/302; 430/913; 430/914; 430/944; 430/945

(57) ABSTRACT

A planographic printing plate precursor of the present invention includes a hydrophilic support, and a lower layer and an image recording layer disposed on the hydrophilic support in this order. The lower layer includes a water-insoluble and alkali-soluble resin, and wherein the image recording layer includes a novolak type phenolic resin containing phenol as a structural unit thereof and a light-to-heat conversion agent, and exhibits increased solubility in an alkaline aqueous solution when exposed to an infrared laser.

### CROSS-REFERENCE TO RELATED APPLICATION

This application claims priority under 35 USC 119 from Japanese Patent Application No. 2003-11024, the disclosure of which is incorporated by reference herein.

### BACKGROUND OF THE INVENTION

1. Field of the Invention

The present invention relates to a planographic printing plate precursor. Particularly, the invention relates to a positive planographic printing plate precursor for an infrared laser used in so-called direct plate-making in which a printing plate can be made directly from digital signals of a computer or the like.

2. Description of the Related Art

The development of lasers has been remarkable in recent years, and particular, solid state lasers and semiconductor lasers having reduced size and a light emission region ranging from near infrared to infrared with high output have become readily available. Such lasers are very useful as exposure light sources in direct plate-making from digital data of a computer or the like.

Positive image recording layers each include a binder resin that is soluble in an alkali aqueous solution and a dissolution inhibitor substantially reducing a solubility of the binder resin by an interaction with the binder resin. In addition to the binder resin and the dissolution inhibitor, preferably included in a positive image recording layer using an infrared laser in exposure is a light-to-heat conversion agent such as an infrared absorbing dye that absorbs light to generate heat.

Among such light-to-heat conversion agents, a cyanine dye is especially preferably used as a light-to-heat conversion agent in an infrared-compatible positive image recording layer since the dye can also function as the dissolution inhibitor.

In such a positive image recording material for an infrared laser, however, a sufficient difference in solubility resistance in a developing solution is still not obtained between a non-exposed area (an imaging area) and an exposed area (a non-imaging area) under various conditions for use. This leads to a problem in which overdevelopment or another development defect can easily occur due to alterations in conditions for use.

Moreover, despite obtaining sufficient energy for an image forming reaction on a laser light irradiated surface of a photosensitive, great heat diffusion into a support occurs, especially in the case where a general-purpose aluminum support is used as the support because of its good heat conductivity. This results in insufficient utilization of the energy for image formation, creating a problem of low sensitivity.

In order to solve the above problems, a planographic printing plate precursor has been proposed in Japanese Patent Application Laid Open (JP-A) No. 11-218914 which has a recording layer comprising a lower layer that includes an acrylic resin and is excellent in alkali-solubility and an upper layer that includes a water-insoluble and alkali-soluble resin and a light-to-heat conversion agent and exhibits greatly increased solubility in an alkaline aqueous solution when exposed to light. The planographic printing plate precursor has an effect such that when a recording layer is removed in an exposed region, a lower layer which is excellent in alkali-solubility is exposed, and an undesired residual film and the like is quickly removed by the alkaline developing solution, and another effect such that the lower layer functions as a heat insulating layer to effectively suppress heat diffusion to a support.

There has been concern that, in order to obtain such a two layer structure, an interaction decreases between the two layers, which in turn reduces scratch resistance in the case where an alkaline developing solution high in concentration is employed in development, thereby resulting in a narrowed development latitude. Thus, there is a need in the art for improved layered structures for use in planographic printing precursors.

### SUMMARY OF THE INVENTION

It is an object of the present invention, which has been made in light of deficiencies of the conventional art, to provide a heat mode-compatible positive planographic printing plate precursor, in which improvement is achieved on scratch resistance on the high alkali concentration side while maintaining a high sensitivity in a recording layer of a layered structure whereby a development latitude is extended, and which is capable of forming an image excellent in contrast and has printing durability and chemical resistance.

The present inventors have found as a result of a earnest study that the above object is achieved by forming a lower layer and an image recording layer having respective components whose solubility is different and abutting each other on a support, which led to completion of the invention.

The invention provides a positive planographic printing plate precursor comprising a hydrophilic support, and a lower layer and an image recording layer disposed on the hydrophilic support in this order, wherein the lower layer includes a water-insoluble and alkali-soluble resin, and wherein the image recording layer includes a novolak type phenolic resin containing phenol as a structural unit thereof and a light-to-heat conversion agent, and exhibits increased of increasing solubility in an alkaline aqueous solution when exposed to an infrared laser.

The operational mechanism of the invention, which is not entirely clear, is considered to be as follows. The novolak type phenolic resin which has phenol as a structural unit thereof, and which is included in the image recording layer of the invention, has an aromatic ring having a phenolic hydroxyl group in a molecule. Therefore, the resin is excellent in solubility in an alkali aqueous solution at an exposed portion thereof and further excellent in the effect of decreasing a residual film of a non-imaging portion even in a low exposure region. Such a characteristic is added to an effect of the lower layer, which is formed between the support and the image forming layer, and which is excellent in solubility, and a combination of these effects enables an image that is excellent in not only discrimination but also contrast to be formed even in a low exposure region, thereby enabling a sensitivity improving effect to be achieved. Moreover, since a film quality is improved by phenol included in a molecule and adhesion is increased between the lower and upper layers, improvement is also realized with respect to scratch resistance, especially an effect of suppressing a scratch caused by the influence of a high concentration alkali aqueous solution, resulting in extension of development latitude. Furthermore, since this novolak type phenolic resin is excellent in stability as a characteristics of the compound itself, reduction in developability caused by a change in the compound over time is suppressed even in long term storage though the compound has a development promoting effect, leading to excellent storage stability of the planographic printing plate precursor.

The planographic printing plate precursor of the invention has a layered structure in which the lower layer, which is not only excellent in solubility, but also strong in chemical resistance, is provided and, as an upper layer thereof, the image recording layer including the novolak type phenolic resin as described above is further provided thereon. Therefore, it is inferred that the planographic printing plate precursor is further provided with an effect of increasing printing durability and chemical resistance due to the presence of the lower layer, and characteristics of the upper layer (the image recording layer) and the lower layer are effectively utilized, thereby enabling the excellent combined effects of the invention to be exerted.

### DETAILED DESCRIPTION OF THE INVENTION

A planographic printing plate precursor of the present invention will be described in detail below.

The planographic printing plate precursor of the invention comprises a hydrophilic support, and a lower layer and an image recording layer disposed on the hydrophilic support in this order, wherein the lower layer includes a water-insoluble and alkali-soluble resin, and wherein the image recording layer includes a novolak type phenolic resin containing phenol as a structural unit thereof and a light-to-heat conversion agent, and exhibits increased solubility in an alkaline aqueous solution when exposed to an infrared laser.

First, description will be given of the image recording layer, which is a characteristic element of the invention.

The image recording layer related to the invention (an upper layer) is required to include the novolak type phenolic resin containing phenol as a structural unit thereof (which is hereinafter appropriately referred to as a specific novolak resin). This specific novolak resin is not particularly limited, and may be any of novolak resins each containing phenol as a structural unit in a molecule. The phenol as a structural unit in a specific novolak resin is preferably contained in the range of from 20 to 90% by mole, more preferably in the range of from 31 to 85% by mole and most preferably in the range of from 51 to 80% by mole among structural units constituting the specific novolak resin.

A preferable example of the specific novolak resin is (A) a resin obtained by condensing of phenol and a substituted phenol expressed by the following general formula (1) with an aldehyde. A more preferable example of the specific novolak resin is a resin selected from (B) resins obtained by condensing of phenol and at least one of cresol and xylenol with an aldehyde.

Herein, the specific novolak resin may include plural kinds of substituted phenols, which are structural units other than the phenol, as components.

The image recording layer related to the present invention is required to further include a light-to-heat conversion agent (C) described below.

First of all, detailed description will be given of (A) a resin obtained by condensing of phenol and a substituted phenol represented by the following general formula (I) with an aldehyde (hereinafter appropriately referred to as resin (A)).

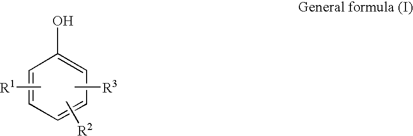

In general formula (I), R¹ and R² each independently represent a hydrogen atom, an alkyl group or a halogen atom. The alkyl group preferably has 1 to 3 carbon atoms and more preferably has 1 or 2 carbon atoms, and the halogen atom is one of fluorine, chlorine, bromine and iodine and is preferably chlorine or bromine. R³ represents an alkyl group or a cycloalkyl group having 3 to 6 carbon atoms.

Specific examples of substituted phenols expressed by general formula (I) and used as a component of the resin (A) include isopropyl phenol, t-butyl phenol, t-amyl phenol, hexyl phenol, cyclohexyl phenol, 3-methyl-4-chloro-6-t-butyl phenol, isopropyl cresol, t-butyl cresol and t-amyl cresol. Preferable examples include t-butyl phenol and butyl cresol.

Examples of aldehydes used in the resin (A) include aliphatic aldehydes and aromatic aldehydes such as formaldehyde, acetaldehyde, acrolein, crotonaldehyde and the like, preferable examples include formaldehyde and acetaldehyde.

A phenol content in monomers constituting the resin (A) is preferably in the range of from 21 to 90% by mole, more preferably in the range of from 31 to 85% by mole, and most preferably in the range of from 51 to 80% by mole.

A weight average molecular weight of the resin (A) is preferably in the range of from 500 to 50,000, more preferably in the range of from 700 to 20,000, and most preferably in the range of from 1,000 to 10,000.

A proportion of the resin (A) relative to a total solid content of the image recording layer of the planographic printing plate precursor of the invention is preferably in the range of from 0.1% by weight to 20% by weight, more preferably in the range of from 0.2% by weight to 10% by weight, and most preferably in the range of from 0.2% by weight to 5% by weight. If the proportion is less than 0.1% by weight, an effect of addition is small, while if the proportion exceeds 20% by weight, a sensitivity tends to decrease.

Next, detailed description will be given of (B) a resin obtained by condensing of phenol and at least one of cresol and xylenol with an aldehyde (hereinafter appropriately referred to as resin (B)) related to the invention.

Aldehydes used in a condensation reaction to obtain the resin (B) are similar to those described in connection with the resin (A).

Preferable examples of the resin (B) used in the invention include novolak resins such as phenol-formaldehyde resin, phenol/cresol (which may be any of m-cresol, p-cresol and m-/p-mixed cresol) mixed formaldehyde resin and the like.

A phenol content in monomers constituting the resin (B) is preferably in the range of from 21 to 90% by mole, more preferably in the range of from 31 to 85% by mole, and most preferably in the range of from 51 to 80% by mole. It is preferable to include m-cresol in an amount of 10% by mole or more in the monomers.

A weight average molecular weight of the resin (B) is preferably in the range of from 500 to 50,000, more preferably in the range of from 700 to 20,000, and most preferably in the range of from 1000 to 10000. A number average molecular weight thereof is preferably 500 or more and more preferably in the range of from 750 to 650,000. A degree of dispersion (a weight average molecular weight/a number average molecular weight) is preferably in the range of from 1.1 to 10.

A content of the resin (B) used in the invention is preferably in the range of from 10% by weight to 95% by weight, and more preferably in the range of from 20% by weight to 90% by weight based one the total solid content of the image recording layer of the planographic printing plate precursor. If the content is 10% by weight or less, cases arise where a effect of improving printing durability by a burning treatment is so small that the planographic printing plate precursor cannot be used.

Specific novolak resins including the resin (A) and the resin (B) related to the invention may be used either alone or in a mixture of two or more kinds.

Typical phenolic type novolak resins other than the specific novolak resin related to the invention can also be used together with one of the specific novolak resin, in which case, one or more novolak resins other than the specific novolak resin can be mixed in the range of from 5 to 50% by weight, preferably in the range of from 5 to 30% by weight, and most preferably in the range of from 5 to 20% by weight based on a total solid content of all the novolak resins. Examples of the novolak resins other than the specific novolak resin includes a resins obtained by condensing the substituted phenol represented by general formula (I) with the aldehyde. Examples of the substituted phenol represented by general formula (I) includes monoalkylphenol, cresol, and xylenol.

A production method of the specific novolak resin related to the invention is described in, for example, Section 300 of “New Experimental Chemistry Lectures [19] Polymer Chemistry [I]” published by Maruzen Co., Ltd. in 1993, wherein phenol and a substituted phenol (for example, cresol or the like, serving as the second component caught up in description of the resin (A) and the resin(B)) are caused to react with formaldehyde added in a state of an aqueous solution in the presence of an acid as a catalyst so that the phenol and the substituted phenol component each are dehydration-condensed with the formaldehyde at the o-position or p-position thereon, thereby enabling the specific novolak resin to be produced.

Dehydration condensation between each of the phenol and the substituted phenol component with formaldehyde at the o-position or p-position thereon can be conducted in a procedure in which formaldehyde is added into a solution of the phenol and the substituted phenol component dissolved in a solvent such that a content of the formaldehyde is generally in the range of from 0.2 to 2.0, preferably in the range of from 0.4 to 1.4, and more preferably in the range of from 0.6 to 1.2 in a molar ratio relative to total moles of the phenol and the substituted phenol component, and a concentration of the phenol and the substituted phenol component combined is generally in the range of from 60 to 90% by weight and preferably in the range of from 70 to 80% by weight relative to a total weight of the solution; an acid catalyst is further added into the solution generally in the range of from 0.01 to 0.1 and preferably in the range of from 0.02 to 0.05 in molar ratio relative to the total moles of the phenol and the substituted phenol component at a temperature in the range of from 10° C. to 150° C.; and the solution is agitated for a few hours while maintaining the temperature in the range. Note that a reaction temperature is preferably in the range of from 70° C. to 150° C. and more preferably in the range of from 90° C. to 140° C.

Examples of solvents used in the production include water, acetic acid, methanol, ethanol, 2-propanol, 2-methoxyethanol, ethylpropionate, ethoxyethylpropionate, 4-methyl-2-pentanone, dioxane, xylene, benzene and the like.

Examples of the acid catalyst include hydrochloric acid, sulfuric acid, p-toluenesulfonic acid, phosphoric acid, oxalic acid, tartaric acid, citric acid, zinc acetate, manganese acetate, cobalt acetate, magnesium methylsulfonate, aluminum chloride, zinc oxide and the like.

Residual monomers and dimers of the synthesized phenol resin are distilled off so that a concentration of the residual monomers and dimers combined is preferably in the range of from 0.01% by weight to 10% by weight and more preferably in the range of from 0.01 to 2.0% by weight.

Specific examples [(S-1) to (S-16)] of specific novolak resins preferably used in the invention are shown below:

(S-1) condensation polymerization product of phenol, m-cresol and p-cresol

(molar ratio=30:50:20, weight average molecular weight=4,000)

(S-2) condensation polymerization product of phenol, m-cresol and o-cresol

(molar ratio=50:30:20, weight average molecular weight=5,500)

(S-3) condensation polymerization product of phenol, m-cresol and p-cresol

(molar ratio=70:10:20, weight average molecular weight=4,500)

(S-4) condensation polymerization product of phenol, m-cresol and p-cresol

(molar ratio=50:30:20, weight average molecular weight=4,200)

(S-5) condensation polymerization product of phenol and m-cresol

(molar ratio=70:30, weight average molecular weight=4,500)

(S-6) condensation polymerization product of phenol and p-cresol

(molar ratio=60:40, weight average molecular weight=6,000)

(S-7) condensation polymerization product of phenol and o-cresol

(molar ratio=50:50, weight average molecular weight=3,900)

(S-8) condensation polymerization product of phenol and p-ethylphenol

(molar ratio=40:60, weight average molecular weight=4,000)

(S-9) condensation polymerization product of phenol and p-tertiary butylphenol

(molar ratio=80:20, weight average molecular weight=5,000)

(S-10) condensation polymerization product of phenol and 2,5-xylenol

(molar ratio=90:10, weight average molecular weight=8,000)

(S-11) condensation polymerization product of phenol and 2,3-xylenol

(molar ratio=75:25, weight average molecular weight=4,400)

(S-12) condensation polymerization product of phenol and 2,4 xylenol

(molar ratio=80:20, weight average molecular weight=5.500)

(S-13) condensation polymerization product of phenol and 3,4 xylenol

(molar ratio=70:30, weight average molecular weight=7,400)

(S-14) condensation polymerization product of phenol and p-nonylphenol

(molar ratio=30:70, weight average molecular weight=9,800)

(S-15) condensation polymerization product of phenol and p-phenylphenol

(molar ratio=65:45, weight average molecular weight=4,000)

(S-16) condensation polymerization product of phenol and o-phenylphenol

(molar ratio=50:50, weight average molecular weight=4,500)

(S-17) condensation polymerization product of phenol, m-cresol and 2,5-xylenol

(molar ratio=80:15:5, weight average molecular weight=5,500)

(S-18) condensation polymerization product of phenol, m-cresol and p-phenylphenol

(molar ratio=40:10:50, weight average molecular weight=4500)

Among these examples, (S-1) to (S-13) are preferable, and (S-1) to (S-8) are more preferable.

In the image recording layer related to the invention, it is possible to use a water-insoluble and alkali-soluble resin other than the specific novolak resins (hereinafter appropriately referred to as a different alkali-soluble resin) together with the specific novolak resin, and using the different alkali-soluble resin together with the specific novolak resin is preferable from the viewpoint of extension of development latitude.

Examples of the different water-insoluble and alkali-soluble resin include resins selected from the group consisting of a polyamide resin, an epoxy resin, an acetal rein, an acrylic resin, a methacrylic resin, a styrene based resin and a urethane resin. Specific examples of the different alkali-soluble resin include a alkali-soluble resin disclosed in paragraphs [0032] to [0053] of JP-A 2003-337405, polyhydroxystyrene, polyhalogenated hydroxystyrene, N-(4-hydroxyphenyl)methacrylamide copolymer, hydroquinone-monomethcrylate copolymer, a sulfonylimide based polymer described in JP-A No. 7-28244, a carboxyl group containing polymer described in JP-A No. 7-36184 and the like. Additional examples thereof include various kinds of alkali-soluble polymeric compounds such as a phenolic hydroxyl group containing acrylic resin as disclosed in JP-A No. 51-34711, a sulfonamide group containing acrylic resin described in JP-A No. 2-866, and a urethane based resin.

The different alkali-soluble resin preferably has a weight average molecular weight in the range of from 500 to 200,000 and a number average molecular weight in the range of from 200 to 60,000.

Such different alkali-soluble resins may be used either alone or in a combination of two or more kinds, and an added amount thereof that can be used together with a specific novolak resin is preferably in the range of from 0.5 to 30% by weight and more preferably in the range of from 0.5 to 20% by weight of the total solid content of the recording layer.

No specific limitation is placed on an absorption wavelength of a light-to-heat conversion agent (C) used in the invention as far as the light-to-heat conversion agent (C) absorbs light energy irradiation rays to generate heat. Light-to-heat conversion agents (C) that can be preferably exemplified include various kinds of dyes or pigments known as infrared absorbing dyes or pigments each having the absorption maximum in the range of from 700 nm to 1200 nm in wavelength in consideration of compatibility with a high output laser that can be obtained with ease.

Dyes that can be used are known dyes on the market that, for example, are described in literatures such as “Dye Manual” (edited by The Society of Synthetic Organic Chemistry, Japan, published in 1970). Specific examples thereof include an azo dye, a metal complex azo dye, a pyrazolone azo dye, a naphtoquinone dye, an anthraquinone dye, a phthalocyanine dye, a carbonium dye, a quinoneimine dye, a methine dye, a cyanine dye, a squarylium dye, a pyrylium salt, a metal thiolate complex, an oxonol dye, a diimmonium dye, an aminium dye, a croconium dye and the like.

Preferable examples of dyes include cyanine dyes described in JP-A Nos. 58-125246, 59-84356, 59-202829, 60-78787 and the like, methine dyes described in JP-A Nos. 58-173696, 58-181690, 58-194595 and the like, naphtoquinone dyes described in JP-A Nos. 58-112793, 58-224793, 59-48187, 59-73996, 60-52940, 60-63744 and the like, squarylium dyes described in JP-A No. 58-112792 and the like and cyanine dyes described in U.K. Patent No. 434,875.

Additional preferable examples include a near-infrared absorbing sensitizer described in U.S. Pat. No. 5,156,938, an arylbenzo(thio)pyrylium salt described in U.S. Pat. No. 3,881,924, a trimethinethiapyrylium salt described in JP-A No. 57-142645 (U.S. Pat. No. 4,327,169), pyrylium based compounds described in JP-A Nos. 58-181051, 58-220143, 59-41363, 59-84248, 59-84249, 59-146063 and 59-146061, a cyanine dye described in JP-A No. 59-216146, a pentamethinethiopyrylium salt and the like described in U.S. Pat. No. 4,283,475 and a pyrylium compound disclosed in Japanese Patent Application Publication (JP-B) Nos. 5-13514 and 5-19702.

Another preferable examples of dyes include near-infrared absorbing dyes described in formulae (I) and (II) in U.S. Pat. No. 4,756,993.

Among the above dyes, especially preferable ones are a cyanine dye, a phthalocyanine dye, an oxonol dye, a squarylium dye, a pyrylium salt, a thiopyrylium dye and a nickel thiolate complex. Furthermore, dyes expressed by the following general formulae (a) to (e) are preferable because of excellent light-to-heat conversion efficiency, wherein a cyanine dye expressed by the following formula (a) is most preferable since in the case where the cyanine dye is used in an image recording layer of the invention, the cyanine dye shows a high interaction with an alkali-soluble resin and is excellent in stability and economics.

General Formula (a)

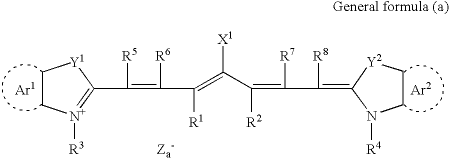

In the general formula (a), X¹ represents a hydrogen atom, a halogen atom, —NPh₂, X²-L¹ or a group shown below; X² represents an oxygen atom or a sulfur atom; and L¹ represents a hydrocarbon group having 1 to 12 carbon atoms, an aromatic ring having a hetero atom or a hydrocarbon group having a hetero atom, and having 1 to 12 carbon atoms, wherein a hetero atom means N, S, O, a halogen atom or Se.

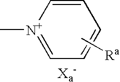

In the above formula, Xa⁻ is defined in a similar manner to that of Za⁻, R^{a} represents a substituent group selected from the group consisting of a hydrogen atom, an alkyl group, an aryl group, a substituted or non-substituted amino group and a halogen atom.

In general formula (a), R¹ and R² each independently represents a hydrocarbon group having 1 to 12 carbon atoms. R¹ and R² each are preferably a hydrocarbon group having 2 or more carbon atoms, and especially preferably bond with each other to form a 5- or 6-membered ring, form the viewpoint of storage stability of a recording layer coating solution.

Ar¹ and Ar² may be the same as or different from each other and represent an aromatic hydrocarbon group that may have a substituent group. Preferable aromatic hydrocarbon groups include a benzene ring and a naphthalene ring. Preferable examples of the substituent group include a hydrocarbon group having 12 or less carbon atoms, a halogen atom and an alkoxy group having 12 or less carbon atoms. Y¹ and Y² are the same as or different from each other and represent a sulfur atom or a dialkylmethylene having 12 or less carbon atoms. R³ and R⁴ may be the same as or different from each other and represents a hydrocarbon group, which may have a substituent group thereof, and which has 20 or less carbon atoms. Preferable examples of the substituent group include an alkoxy group having 12 or less carbon atoms, a carboxylic group and a sulfo group. R⁵, R⁶, R⁷ and R⁸ may be the same as or different from one another and represent a hydrogen atom or a hydrocarbon group having 12 or less carbon atoms. Preferable R⁵, R⁶, R⁷ and R⁸ are a hydrogen atom from the viewpoint of availability of a raw material. Za⁻ represents a counter anion. No necessity arises for Za⁻, however, in the case where a cyanine dye expressed by the general formula (a) has an anionic substituent group in a molecular structure and no necessity arises for neutralizing an electric charge thereof. Preferable examples of Za⁻ include a halogen ion, a perchlorate ion, a tetrafluoroborate ion, a hexafluorophosphate ion and a sulfonate ion, and more preferable are a perchlorate ion, a hexafluorophosphate ion and an arylsulfonate ion, from the viewpoint of storage stability of a recording layer coating solution.

Preferable specific examples of cyanine dyes expressed by the general formula (a) in the invention include dyes described in paragraphs [0017] to [0019] of JP-A No. 2001-133969, paragraphs [0012] to [0038] of JP-A No. 2002-40638 and paragraphs [0012] to [0023] of JP-A No. 2002-23360 in addition to the dyes shown below.

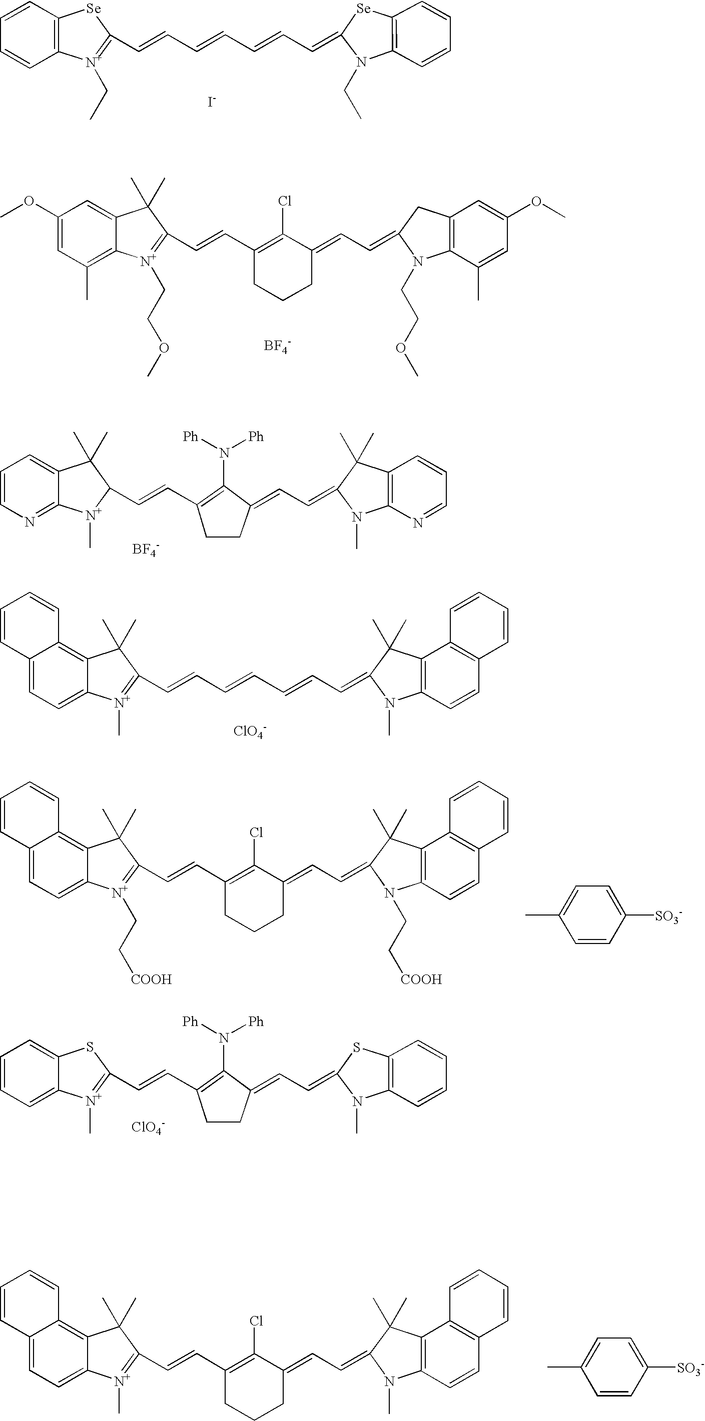

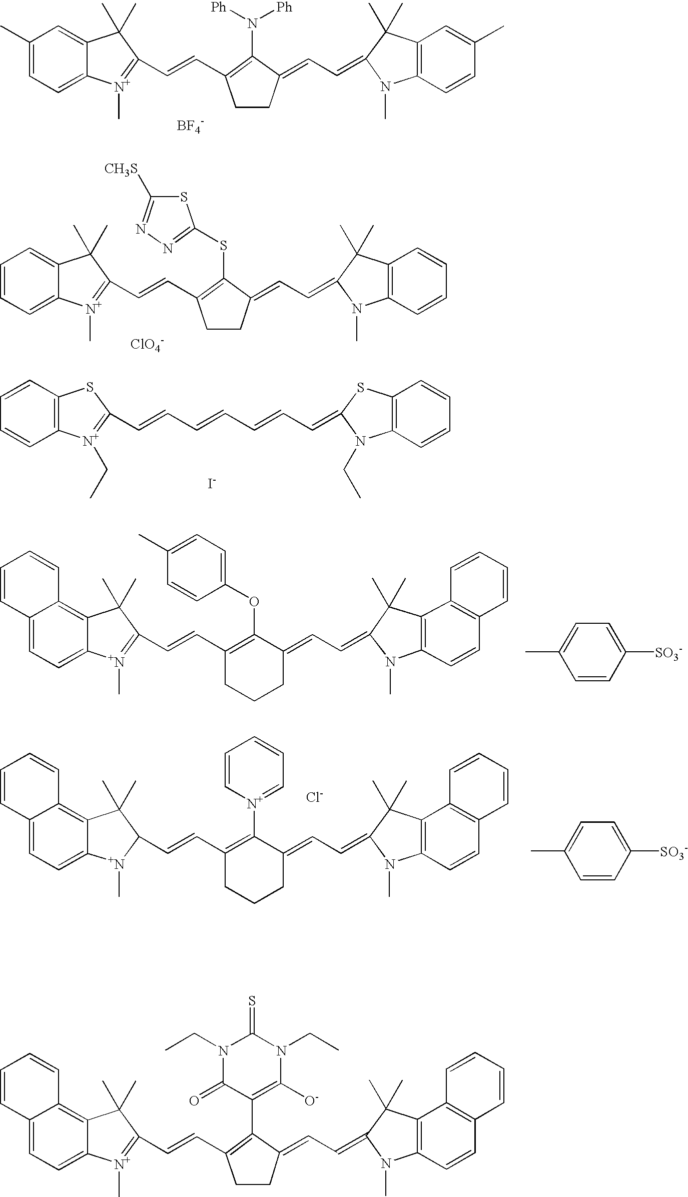

General Formula (b)

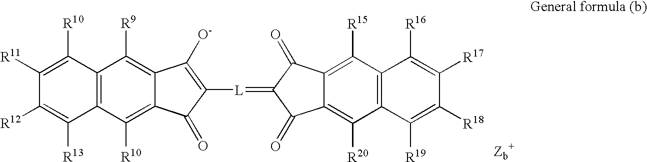

In the general formula (b), L represents a methine chain having 7 or more conjugated carbon atoms, wherein the methine chain may have a substituent group, and the substituent groups may bond together to form a ring structure; Zb⁺ represents a counter cation, and examples of preferable counter cations include an ammonium cation, an iodonium cation, a sulfonium cation, a phosphonium cation, a pyrydinium cation, an alkali metal cation (Na⁺, K⁺ and Li⁺) and the like; and R⁹ to R¹⁴ and R¹⁵ to R²⁰ each independently represents a substituent group selected from the group consisting of a hydrogen atom, a halogen atom, a cyano group, an alkyl group, an aryl group, an alkenyl group, an alkynyl group, a carbonyl group, a thio group, a sulfonyl group, a sulfinyl group, an oxy group and an amino group, or a substituent group obtained by combining two or three groups selected from these groups. R¹ to R¹⁴ and R¹⁵ to R²⁰ may bond together to form a ring structure. In the general formula (b), L preferably represents a methine chain having 7 or more conjugated carbon atoms, and R⁹ to R¹⁴ and R¹⁵ to R²⁰ each preferably represents a hydrogen atom, from the viewpoint of availability of a raw material.

Specific examples of dyes represented by the general formula (b) that can be preferably used in the invention include the following dyes.

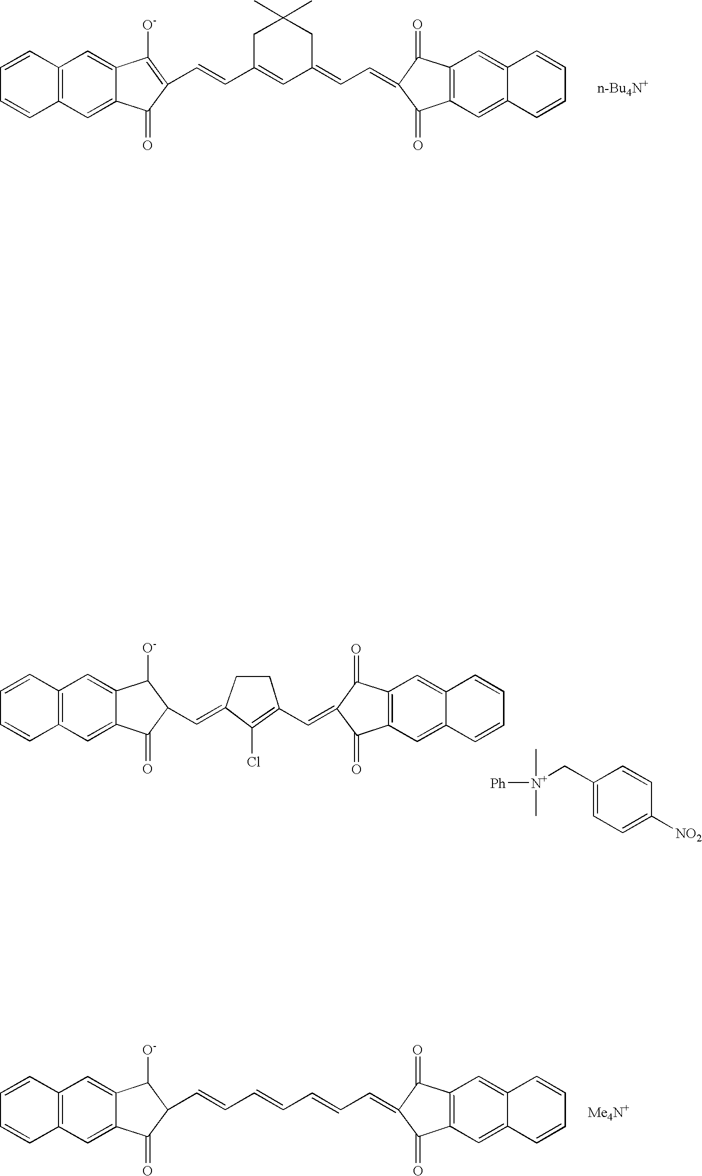

General Formula (c)

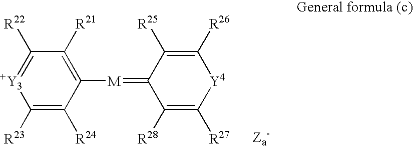

In the general formula, Y³ and Y⁴ each independently represent, an oxygen atom, a sulfur atom, a selenium atom, or a tellurium atom; M represents a methine chain having 5 or more conjugated carbon atoms; R²¹ to R²⁴ and R²⁵ to R²⁸ may be the same as or different from one another and represent a hydrogen atom, a halogen atom, a cyano group, an alkyl group, an aryl group, an alkenyl group, an alkynyl group, a carbonyl group, a thio group, a sulfonyl group, a sulfinyl group, an oxy group or an amino group; Za⁻ represents a counter anion, which has the same meaning as Za⁻ in the general formula (a).

Specific examples of dyes represented by the general formula (c) that can be preferably used in the invention include the following dyes.

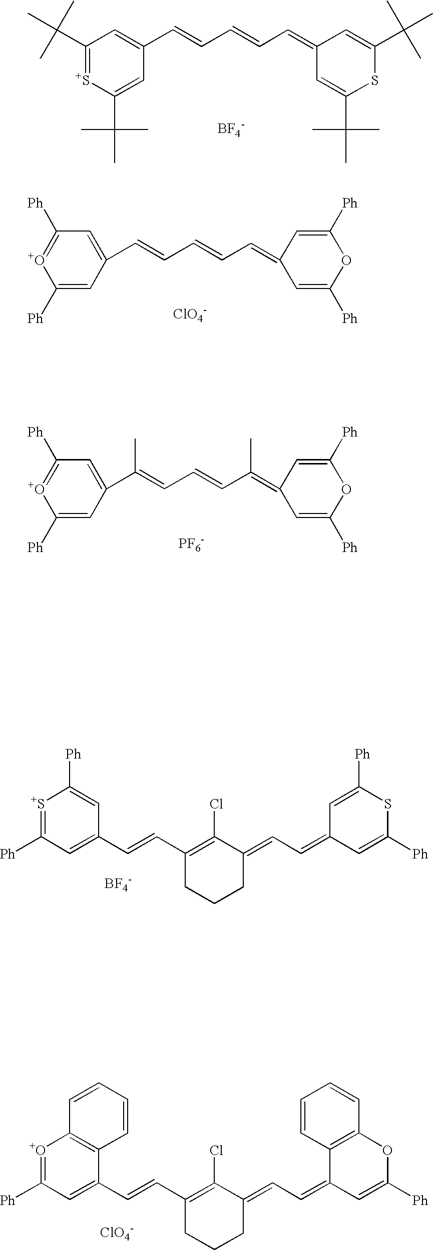

General Formula (d)

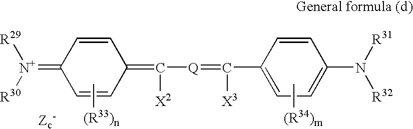

In the genral formula (d), R²⁹, R³⁰, R³⁰, R³¹ and R³² each independently represent a hydrogen atom, an alkyl group or an aryl group; R³³ and R³⁴ each independently represent an alkyl group, a substituted oxy group or a halogen atom; n and m each independently represent an integer from 0 to 4; a pair of R²⁹ and R³⁰ and a pair of R³′ and R³² may bond together to form a ring, R²⁹ and/or R³⁰ may bond with R³³ to form a ring and R³¹ and/or R³² may bond with R³⁴ to form a ring, in the case where there are plural R³³s or plural R³⁴s, R³³s or R³⁴s may bond together to form a ring; X² and X³ each independently represent a hydrogen atom, an alkyl group or a aryl group and at least one of X² and X³ represent a hydrogen atom or an alkyl group; Q is a trimethine group that may have a substituent group thereon or a pentamethine group that may have a substituent group thereon and may form a ring structure with a divalent organic group; and Zc⁻ represents a counter anion, which has the same meaning as Za⁻ in the general formula (a).

Specific examples of dyes represented by the general formula (d) that can be preferably used in the invention include the following dyes.

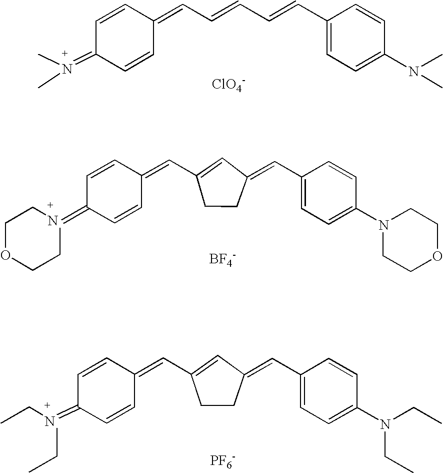

General Formula (e)

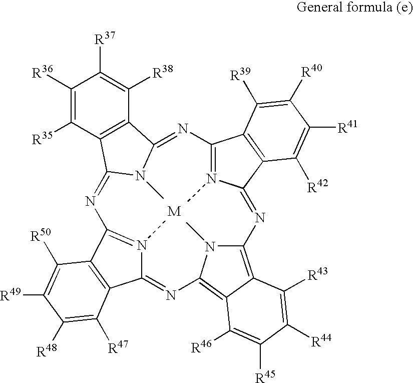

In the general formula (e), R³⁵ to R⁵⁰ each independently represent a hydrogen atom, a halogen atom, a cyano group, an alkyl group, an aryl group, an alkenyl group, an alkynyl group, a hydroxyl group, a carbonyl group, a thio group, a sulfonyl group, a sulfinyl group, an oxy group, an amino group or an onium salt structure, wherein in the case where a substituent group can be introduced thereinto, the substituent group may be included therein; M represents two hydrogen atoms, two metal atoms, two halometal groups or two oxymetal groups, wherein metal atoms included therein are preferably atoms selected from the group consisting of atoms of groups IA, IIA, IIIB and IV, atoms of transition metals of the first to third periods and atoms of lanthanoid elements of the periodic table, among which preferable are copper, magnesium, iron, zinc, cobalt, aluminum, titanium and vanadium.

Specific examples of dyes represented by the general formula (e) that can be preferably used in the invention include the following dyes.

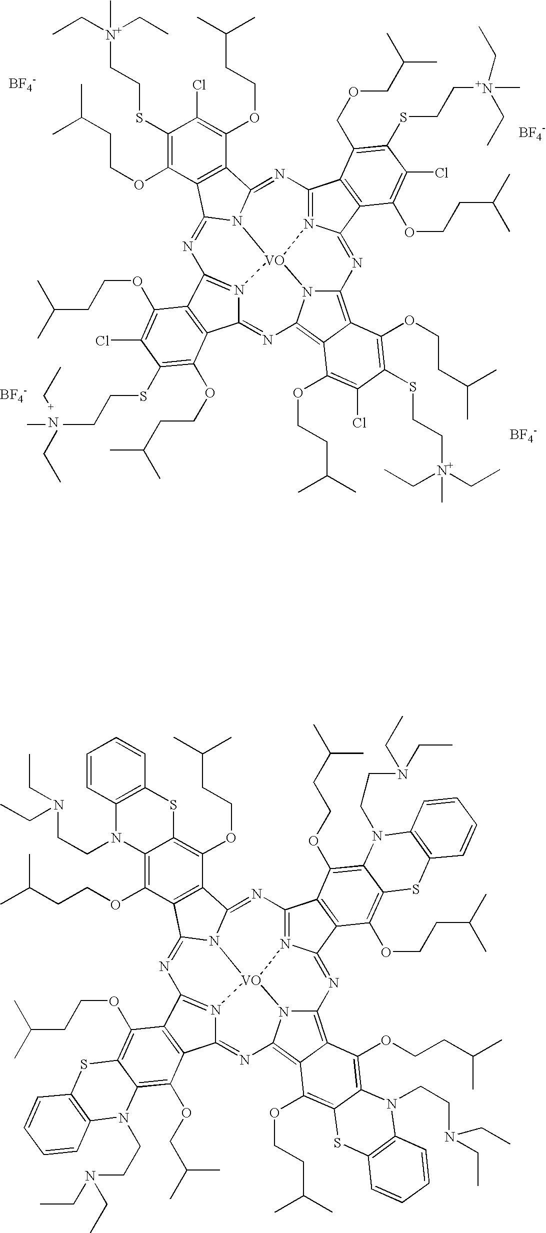

As pigments that are used as the Light-heat Converting agent in the invention can be utilized commercially available pigments and pigments described in “Color Index (C. I.) Manual,” “Current Pigment Manual” edited by Nippon Ganryo Gijutsu Kyokai, published in 1977, “Latest Pigment Application Technology” published by CMC Publishing Co., Ltd., in 1986, and “Printing Ink Technology” published by CMC Publishing Co., Ltd., in 1984.

Examples of the pigments include a black pigment, a yellow pigment, an orange pigment, a brown pigment, a red pigment, a purple pigment, a blue pigment, a green pigment, a fluorescent pigment, a metal powder pigment and a polymer coupled dye. Specific examples of pigments include an insoluble azo pigment, an azo lake pigment, a condensed azo pigment, a chelate azo pigment, a phthalocyanine based pigment, an anthraquinone based pigment, a prylene and perynone based pigment, a thioindigo based pigment, a quinacridone based pigment, a dioxazine based pigment, an isoindolinone based pigment, a quinophthalone based pigment, a dyeing lake pigment, an azine pigment, a nitroso pigment, a nitro pigment, a natural pigment, a fluorescent pigment, an inorganic pigment, carbon black and the like, among which carbon black is preferable.

These pigments may be used without being subjected to surface processing, or may be used after being subjected to surface processing. Examples of surface treatment methods include a method in which resin or wax is surface coated, a method in which a surfactant is attached thereon, a method in which a reactive substance (for example, a silane coupling agent, an epoxy compound, a polyisocyanate or the like) is coupled to surfaces of pigment particles and the like. The surface treatment methods are described in “Quality and Applications of Metal Soap” published by Saiwai Shobo, “Printing Ink Technology” published by CMC Publishing Co., Ltd., in 1984 and “Latest Pigment Application Technology” published by CMC Publishing Co., Ltd., in 1986.

Diameters of particles of the pigment are preferably in the range of 0.01 to 10 μm, more preferably in the range of from 0.05 to 1 μm and particularly preferably in the range of from 0.1 to 1 μm from the viewpoint of stability of pigment dispersing particles in an image forming layer coating solution and uniformity of the image forming layer.

As a method dispersing a pigment include, a known dispersing technology can be applied that has been employed in ink manufacture, toner manufacture and the like. Examples of dispersion mixers include an ultrasonic dispersing machine, a sand mill, an attritor, a pearl mill, a super mill, a ball mill, an impellor, a disperser, a KD mill, a colloid mill, dynatron, a three roll mill, a pressure kneader and the like. Details of the dispersing technology are described in “Latest Pigment Application Technology” published by CMC Publishing Co., Ltd., in 1986.

The pigment or dye can be added in the image forming layer in the range of from 0.01 to 50% by weight and preferably in the range of from 0.1 to 10% by weight relative to a total solid content included in the image forming layer from the viewpoint of sensitivity, uniformity, and durability of the image forming layer. In the case where only a dye is used, the dye can be most preferably added in the range of from 0.5 to 10% by weight, while in the case where only a pigment is used, the pigment is most preferably added in the range of from 3.1 to 10% by weight with the same reference.

Then, description will be given of other components that can be added into a coating solution composition for the image recording layer, in preparation thereof, in the planographic printing plate precursor of the invention.

Various kinds of additives can be used together with the essential components if necessary as far as an additive does not degrade the effect of the invention by any extent.

Specifically, from the viewpoint of enhancing dissolution inhibition of image areas into the developing solution, it is preferred to jointly use substances that are heat decomposable and in a non-decomposed state, substantially reduce dissolution of the alkali-soluble high-molecular compound, such as onium salts, o-quinonediazide compounds, aromatic sulfone compounds, and aromatic sulfonic acid ester compounds. Examples of other onium salts include oniums other than the onium salts falling within the scope of the compound represented by the foregoing general formula (1), such as diazonium salts, ammonium salts, phosphonium salts, iodonium salts, sulfonium salts, selenonium salts, arsonium salts, and azinium salts.

Suitable examples of other onium salts that are used in the invention include diazonium salts described in S. I. Schlesinger, Photogr. Sci. Eng., 18, 387 (1974), T. S. Bal, et al., Polymer, 21, 423 (1980), and JP-A No. 5-158230; ammonium salts described in U.S. Pat. Nos. 4,069,055 and 4,069,056 and JP-A No. 3-140140; phosphonium salts described in D. C. Necker, et al., Macromolecules, 17, 2468 (1984), C. S. Wen, et al., Teh, Proc. Conf. Rad. Curing, ASIA, p.478, Tokyo, Oct (1988), and U.S. Pat. Nos. 4,069,055 and 4,069,056; iodonium salts described in J. V. Crivello, et al., Macromolecules, 10(6), 1307 (1977), Chem. & Eng. News, Nov., 28, p.31 (1988), European Patent No. 104,143, U.S. Pat. Nos. 5,041,358 and 4,491,628, and JP-A Nos. 2-150848 and 2-296514; sulfonium salts described in J. V. Crivello, et al., Polymer J., 17, 73 (1985), J. V. Crivello, et al., J. Org. Chem., 43, 3055 (1978), W. R. Watt, et al., J. Polymer Sci., Polymer Chem. Ed., 22, 1789 (1984), J. V. Crivello, et al., Polymer Bull., 14, 279 (1985), J. V. Crivello, et al., Macromolecules, 14(5), 1141 (1981), J. V. Crivello, et al., Polymer Sci., Polymer Chem. Ed., 17, 2877 (1979), European Patent Nos. 370,693, 233, 567, 297,443 and 297,442, U.S. Pat. Nos. 4,933,377, 3,902,114, 5,041,358, 4,491,628, 4,760,013, 4,734,444 and 2,833,827, and German Patent Nos. 2,904,626, 3,604,580 and 3,604,581; selenonium salts described in J. V. Crivello, et al., Macromolecules, 10(6), 1307 (1977) and J. V. Crivello, et al., J. Polymer Sci., Polymer Chem. Ed., 17, 1047 (1979); and arsonium salts described in C. S. Wen, et al., Teh, Proc. Conf. Rad. Curing, ASIA, p.478, Tokyo, Oct (1988).

Of these other onium salts are particularly preferable diazonium salts. Further, particularly suitable examples of diazonium salts are those described in JP-A No. 5-158230.

Examples of counter ions of the foregoing other onium salts include tetrafluoroboric acid, hexafluorophosphoric acid, triisopropylnaphthalenesulfonic acid, 5-nitro-o-toluenesulfonic acid, 5-sulfosalicylic acid, 2,5-dimethylbenzenesulfonic acid, 2,4,6-trimethylbenzenesulfonic acid, 2-nitrobenzenesulfonic acid, 3-chlorobenzenesulfonic acid, 3-bromobenzenesufonic acid, 2-fluorocaprylnaphthalenesulfonic acid, dodecylbenzenesulfonic acid, 1-naphthol-5-sulfonic acid, 2-methoxy-4-hydroxy-5-benzoyl-beznenesulfonic acid, and p-toluenesulfonic acid. Of these are particularly suitable hexafluorophosphoric acid, triisopropylnaphthalenesulfonic acid, and alkyl aromatic sulfonic acids such as 2,5-dimethylbenzenesulfonic acid.

Suitable examples of quinonediazides include o-quinonediazide compounds. The o-quinonediazide compound to be used in the invention is a compound containing at least one o-quinonediazide group, whose alkali solubility increases by heat decomposition, and compounds having various structures can be used. Namely, the o-quinonediazide assists dissolution of photosensitive materials due to both of an effect in which it loses dissolution inhibition of a binder by heat decomposition and an effect in which the o-quinonediazide itself converts into an alkali-soluble substance. Examples of o-quinonediazide compounds that are used in the invention include compounds described in J. Kosar, Light-Sensitive Systems, pp.339-352, John Wiley & Sons. Inc. Especially, sulfonic acid esters or sulfonic acid acids of o-quinonediazide reacted with various aromatic polyhydroxy compounds or aromatic amino compounds are suitable. Further, esters of benzoquinone-(1,2)-diazidosulfonic acid chloride or naphthoquinone-(1,2)-diazido-5-sulfonic acid chloride and a pyrrogallol-acetone resin described in JP-B No. 43-28403 and esters of benzoquinone-(1,2)-diazidosulfonic acid chloride or naphthoquinone-(1,2)-diazido-5-sulfonic acid chloride and a phenol-formaldehyde resin described in U.S. Pat. Nos. 3,046,120 and 3,188,210 are also suitably used.

In addition, esters of naphthoquinone-(1,2)-diazido-4-sulfonic acid chloride and a phenol-formaldehyde resin or a cresol-formaldehyde resin and esters of naphthoquinone-(1,2)-diazido-4-sulfonic acid chloride and a pyrrogallol-acetone resin are suitably used, too. Besides, useful o-quinonediazide compounds are reported in and known by various patents such as JP-A Nos. 47-5303, 48-63802, 48-63803, 48-96575, 49-38701 and 48-13354, JP-B Nos. 41-11222, 45-9610 and 49-17481, U.S. Pat. Nos. 2,797,213, 3,454,400, 3,544,323, 3,573,917, 3,674,495 and 3,785,825, British Patent Nos. 1,227,602, 1,251,345, 1,267,005, 1,329,888 and 1,330,932, and German Patent No. 854,890.

The addition amount of the o-quinonediazide compound is preferably in the range of 0.1 to 10% by mass, more preferably 0.1 to 5% by mass, and particularly preferably 0.2 to 2% by mass based on the whole of solid contents of the image forming material. Such o-quinonediazide compounds may be used alone or in admixture.

The addition amount of other additives than the o-quinonediazide compound is preferably in the range of 0 to 5% by mass, more preferably 0 to 2% by mass, and particularly preferably 0.1 to 1.5% by mass based on the whole of solid contents of the image forming material. In the invention, it is preferred to contain the additives and the binder in the same layer.

Further, examples of additives include a cyclic acid anhydride, a phenol and an organic acid for use in enhancing a sensitivity. Other examples thereof include a printing-out agent for obtaining a visible image immediately after exposure, a dye as an image coloring agent, other fillers and the like.

Examples of cyclic acid anhydrides include phthalic anhydride, tetrahydrophthalic anhydride, hexahydrophthalic anhydride, 3,6-endoxy-Δ4-tetrahydrophthalic anhydride, tetrachlorophthalic anhydride, maleic anhydride, chloromaleic anhydride, α-phenylmaleic anhydride, succinic anhydride, pyromellitic anhydride and the like, as described in U.S. Pat. No. 4,115,128. Phenols include bisphenol A, p-nitrophenol, p-ethoxyphenol, 2,3,4-trihydroxybenzophenone, 4-hydroxybenzophenone, 2,4,4′-trihydroxybenzophenone, 4,4′,4″-trihydroxy-triphenylmethane, 4,4′,3″,4″-tetrahydroxy-3,5,3′,5′-tetramethyltriphenylmethane and the like, described in U.S. Pat. No. 4,115,128.

Organic acids include sulfonic acids, sulfinic acids, alkylsufuric acides, phosphonic acids, phosphinic acids, phosphate esters, carboxylic acids and the like described in JP-A Nos. 60-88942 and 2-96755 and specific examples thereof are listed as follows: p-toluenesulfonic acid, dodecylbenzenesulfonic acid, p-toluenesulfinic acid, ethylsulfuric acid, phenylphosphonic acid, phenylphosphinic acid, phenylphosphate, diphenylphosphate, bezoic acid, isophthalic acid, adipic acid, p-toluic acid, 3,4-dimethoxybenzoic acid, phthalic acid, terephthalic acid, 1,4,-cyclohexene-2,2-dicarboxylic acid, erucic acid, lauric acid, n-undecanoic acid, ascorbic acid and the like.

A ratio of each of the cyclic acid anhydrides, the phenols and organic acids in a photosensitive composition is preferably in the 0.05 to 15% by weight, and more preferably in the range of 0.1 to 5% by weight.

A printing-out agents for obtaining a visible image immediately after exposure can be a combination of a photosensitive compound releasing an acid on exposure and an organic dye forming a salt with the acid to alter a color tone.

Examples of photosensitive compounds each releasing an acid on exposure include o-naphthoquinonediazide-4-sulfonic acid halogenide described in JP-A No. 50-36209, trihalomethyl-2-billon and trihalomethyl-s-triazine described in JP-A No. 53-36223, various o-naphtoquinonediazide compounds described in JP-A No. 55-62444, 2-trihalomethyl-5-aryl-1,3,4-oxadiazole compounds and diazonium salts described in JP-A No. 55-77742.

Each of the compounds may be used either alone or in mixture and an additive amount thereof is preferably in the range of from 0.3 to 15% by weight relative to a total weight of the composition.

Into an image recording layer composition, it is possible to add at least one kind of an organic dye altering a color tone of an image recording layer through an interaction with a photolytic product of a compound generating an acidic compound in photolysis.

Examples of such organic dye include diphenylmethane based dyes, triarylmethane based dyes, thiazine based dyes, oxazine based dyes, phenazine based dyes, xanthene based dyes, anthraquinone based dyes, iminonaphthoquinone based dyes, azomethine based dyes. Specific examples thereof are as follows:

Brilliant green, eosin, ethyl violet, erythrocin B, methyl green, crystal violet, basic fuchsine, phenolphthalein, 1,3-diphenyltriazine, alizarine red S, thymolphthalein, methyl violet 2B, quinaldine red, rose bengal, thymolsulfophthalein, xylenol blue, methyl orange, orange IV, diphenylthiocarbazone, 2,7-dichlorofluorescein, paramethyl red, congo red, benzopurpurine 4B, α-naphthyl red, nile blue 2B, nile blue A, phenacetarin, methyl violet, malachite green, parafuchsine, oil blue # 603 (manufactured by Orient Chemical Industries Ltd.), oil pink # 312 (manufactured by Orient Chemical Industries Ltd.), oil red 5B (manufactured by Orient Chemical Industries Ltd.), oil scarlet # 308 (manufactured by Orient Chemical Industries Ltd.), oil red OG (manufactured by Orient Chemical Industries Ltd.), oil red RR (manufactured by Orient Chemical Industries Ltd.), oil green # 502 (manufactured by Orient Chemical Industries Ltd.), spyron red BEH special (manufactured by Hodogaya Chemical Co., Ltd.), victoria pure blue BOH (manufactured by Hodogaya Chemical Co., Ltd.),

patent pure blue (manufactured by Sumitomo Mikuni Chemical Co., Ltd.), sudan blue II (manufactured by BASF Co.), m-cresol purple, cresol red, rhodamine B, rhodamine 6G, first acid violet R, sulforhodamine B, auramine, 4-p-diethylaminophenyliminonaphthoquinone, 2-carboxyanilino-4-p-diethyaminophenyliminonaphtoquinone, 2-carbostearylamino-4-p-dihydroxyethyl-amino-phenyliminonaphthoquinone, p-methoxybenzoyl-p′-diethylamino-o′-methylphenyliminoacetoanilide, cyano-p-diethylaminophenyliminoacetoanilide, 1-phenyl-3-methyl-4-p-diethylaminophenylimino-5-pyrazolone, 1-β-naphthyl-4-p-diethylaminophenylimino-5-pyrazolone and the like.

An especially preferable organic dye is a triarylmethane based dye. Among triarylmethane based dyes, especially useful is an organic dye having a sulfonic acid compound as a counter anion as described in JP-A No. 62-2932471 and JP No. 2969021.

The dyes may be used either alone or in mixture. An additive amount of each of them is preferably in the range of from 0.3 to 15% by weight relative to a total weight of the image recording layer composition.

An organic dye described above can be used together with other kinds of dyes and pigments. Each of the other kinds of dyes and pigments can be used at a proportion of 70% by weight or less and preferably 50% by weight or less relative to a total weight of dyes and pigments in the composition.

Into the image recording layer composition, various other additives can be mixed according to purposes, and examples thereof include: resins each having a hydrophobic group for improvement on inking property of an image, such as octylphenol-formaldehyde resin, t-butylphenol-formaldehyde resin, t-butylphenol-benzaldehyde resin, rosin-modified novolak resin and an o-naphtoquinonediazidesulfonate ester of a rosin-modified novolak resin; plasticizers for improvement on flexibility of a coat such as dibutyl phthalate, dioctyl phthalate, butyl glycolate, tricresyl phosphate, dioctyl adipiate; and the like. An additive amount of an additive described above is preferably in the range of from 0.01 to 30% by weight relative to all the weight of the composition.

Into the image recording layer composition, it is possible to add known resin for further improvement on abrasion resistance of a film. Examples of such resins include polyvinyl acetal resin, polyurethane resin, epoxy resin, vinyl chloride resin, nylon, polyester resin, acrylic resin and the like, which can be used either alone or in mixture. An additive amount of such a resin is preferably in the range of from 2 to 40% by weight relative to a total weight of the composition.

Into the image recording layer composition, it is possible to add nonionic surfactants as described in JP-A Nos. 62-251740 and 4-68355; and ampholytic surfactants as described in JP-A Nos. 59-121044 and 4-13149 to extend a development latitude. Specific examples of nonionic surfactants include sorbitan tristearate, sorbitan monopalminate, sorbitan trioleate, stearic acid monoglyceride, polyoxyethylene solbitan monooleate, polyoxyethylenenonyl phenyl ether and the like and examples of ampholitic surfactants include an alkyldi(aminoethyl)glycine, an alkylpolyaminoethyl glycine chloride, Amogen K (a trade name, manufactured by Dai-ichi Kogyo Seiyaku Co., Ltd., an N-tetradecyl-N,N-betaine type), a 2-alkyl-N-carboxyethyl-N-hydroxyethyl imidazolium betaine, Rebon 15 (a trade name, manufactured by Sanyo Chemical Industries Ltd., an alkylimidazoline based surfactant).

A proportion of a nonionic or ampholytic surfactant described above in the image recording layer composition is preferably in the range of from 0.05% by weight to 15% by weight and more preferably in the range of from 0.1% by weight to 5% by weight.

Into the image recording layer composition, it is possible to add a surfactant for improving a quality of a coat surface, such as a fluorine containing surfactant as described in JP-A No. 62-170950.

An additive amount thereof is preferably in the range of from 0.001 to 1.0% by weight and more preferably in the range of from 0.005 to 0.5% by weight.

Into the image recording layer composition, it is possible to add an yellow dye, preferably a yellow dye having an absorbance at 417 nm is a value of 70% of that at 436 nm or higher.

Then, description will be given of the lower layer. The lower layer is provided between a support, which is described later, and the image recording layer.

The lower layer in the present invention is characterized by containing a water-insoluble and alkali-soluble resin.

Since a lower layer itself is necessary to exert high alkali-solubility especially in a non-imaging region, a necessity arises for selecting such an alkali-soluble resin that is not degraded in the characteristic. From this view point, preferable resins are the different alkali-soluble resins taken up in description of the image recording layer. Among them, it is preferably to select a resin harder to cause an interaction and more excellent in solubility in an alkali developing solution than a specific novolak resin used in the image recording layer in terms of a sensitivity and an image forming property and preferable examples thereof include polyamide resin, epoxy resin, acetal rein, acrylic resin, methacrylic resin, a styrene based resin, urethane resin and the like.

As an alkali-soluble resin used in the lower layer, it is preferable to select a resin hard to be dissolved into a solvent of a coating solution for an image recording layer to be provided on the lower layer when the coating solution is applied thereon. By selecting such a resin, not only is mutual dissolution at an interface between both layers suppressed, but it can also be expected to improve chemical resistance to a higher level. From such a viewpoint, acrylic resin is preferable among the resins.

Description will be given of a water-insoluble and alkali-soluble acrylic resin, which is a preferable alkali-soluble resin preferably used in a lower layer, (hereinafter appropriately referred to simply as acrylic resin). No specific limitation is placed on the acrylic resin as far as it is insoluble in water and soluble in an alkali solution. Since such an acrylic resin is low in mutual solubility with an alkali-soluble resin having a phenolic hydroxyl group, which is preferably used in the upper layer, the acrylic resin itself is especially suited for forming such a layered structure and excellent in alkali-solubility as a characteristic thereof.

Examples of acrylic resins include resins, each having, as a structural component, one or more of alkali-soluble groups such as sulfoamide groups (—SO₂NH—R, wherein R represents a hydrogen atom or a hydrocarbon group that may have a substituent group), active imide groups (—SO₂NHCOR, —SO₂NHSO₂R and —CONHSO₂R, wherein R represents a hydrocarbon group that may have a substituent), a carboxyl group (—CO₂H), a sulfonic group (—SO₃H), a phosphoric group (—OP₃H₂) and the like; and in addition, one or more of acrylate esters, methacrylate esters, alkylacrylates and alkylmethacrylates, each of which has an aliphatic hydroxyl group and suitable as a copolymerizable component of an alkali-soluble resin, one or more of acrylamides and methacrylamides, one or more of inactive imides such as alkylmaleimides and arylmaleimides, and one or more of nitriles such as acrylonirile, methacrylonitrile and the like.

Furthermore, an acrylic resin having a sulfonamide group and the like described in JP-A No. 2-866 are preferably used in the invention.

An weight average molecular weight of the acrylic resin is preferably 2,000 or more and more preferably in the range of from 5,000 to 300,000, while a number average molecular weight thereof is preferably 500 or more and more preferably in the range of from 800 to 250,000 and a degree of dispersion (a weight average molecular weight/a number average molecular weight) is in the range of from 1.1 to 10.

A content of an alkali-soluble resin in lower layer components in the present invention is generally in the range of from about 40 to about 95% by weight and preferably in the range of from about 50 to about 90% by weight.

Into the lower layer, it is possible to use a light-to-heat conversion agent and various additives used in the image recording layer in addition to an alkali-soluble resin described above.

(Production of Planographic Printing Plate Precursor)

The planographic printing plate precursor of the invention can be produced in a procedure that components of the lower layer, components of the positive image recording layer and components of a coating solution for a desired layer described later are dissolved or dispersed into respective solvents to prepare coating solutions, and the coating solutions each are applied on a proper support followed by drying the wet coat.

Any known and common organic solvent can be used as a solvent for a coating solution used in dissolution of components of an image recording layer related to the invention and coating in the form of the solution thereon.

A solvent is preferably selected from solvents having a boiling point in the range of from 40° C. to 200° C. and more preferably in the range of from 60° C. to 160° C. in consideration of advantage in drying.

Preferable examples of organic solvents include alcohols such as methyl alcohol, ethyl alcohol, n-or iso-propyl alcohol, n- or iso-butyl alcohol, diacetone alcohol and the like; ketones such as acetone, methyl ethyl ketone, methyl propyl ketone, methyl butyl ketone, methyl amyl ketone, methyl hexyl ketone, diethyl ketone, diisobutyl ketone, cyclohexanone, methyl cyclohexanone, acetylacetone and the like; hydrocarbons such as benzene, toluene, xylene, cyclohexane, methoxybenzene and the like; acetate esters such as ethyl acetate, n- or iso-propyl acetate, n- or iso-butyl acetate, ethylbutyl acetate, hexyl acetate and the like; halides such as methylene dichloride, ethylene dichloride, monochlorobenzene and the like; ethers such as isopropyl ether, n-butyl ether, dioxane, dimethyldioxane, tetrahydrofuran and the like.

Polyvalent alcohols and derivatives thereof such as ethylene glycol, methyl cellosolve, methyl cellosolve acetate, ethyl cellosolve, diethyl cellosolve, cellosolve acetate, butyl cellosolve, butyl cellosolve acetate, methoxymethoxyethanol, diethylene grycol monomethyl ether, diethylene glycol dimethyl ether, diethylene glycol methylethyl ether, diethylene glycol diethyl ether, propylene glycol, propylene glycol monomethyl ether, propylene glycol monomethlyl ether acetate, propylene glycol monoethyl ether, propylene glycol monoethlyl ether acetate, propylene glycol monobutyl ether, 3-methyl-3-methoxybutanol and the like; and special solvents such as dimethyl sulfoxide, N,N,-dimethylformamide and the like, which are preferably used either alone or in mixture. A concentrations of a solid content in a coating composition in each of the lower layer and the image recording layer is preferably in the range of from 2 to 50% by weight.

Note that the lower layer and the image recording layer provided adjacent thereto are preferably formed in respective two layers separated from each other in principle.

Methods of forming two layers separated from each other include a method using a difference in solubility in a solvent between a component included in a lower layer and a component included in an image recording layer (upper layer), a method in which immediately after an upper layer is coated, a solvent is rapidly removed by drying or the like.

Detailed description will be given of the methods below, however, a method of coating two layers being separated from each other is not limited thereto.

In the method using a difference in solubility in a solvent between a component included in a lower layer and a component included in an image recording layer (upper layer), used in coating the upper layer coating solution is a solvent into which an alkali-soluble resin, which is a main component included in the lower layer, is insoluble. By doing so, even if two layer coating is conducted, two layers can be formed as coats in a clearly separate state therebetween. The two layer structure can be realized in a procedure including a step of selecting, as a lower layer component, a different alkali-soluble resin such as a component insoluble in a solvent such as methyl ethyl ketone, 1-methoxy-2-propanol or the like dissolving an alkali-soluble resin having, as a main component, a specific novolak resin, which is an upper layer component, thereinto, especially preferably an acrylic resin described above or the like, a step of using such a solvent dissolving the lower layer component to form the lower layer by coating, followed by drying, a step of dissolving an upper layer composition including, as a main component, an alkali-soluble resin represented by a specific novolak resin into methyl ethyl ketone, 1-methoxy-2-propanol or the like and a step of applying the coating solution on the lower layer, followed by drying.

In order that after an image recording layer (upper layer) is coated, the solvent therein is removed at an extremely high speed by drying, the following methods can be applied, in one of which a high pressure air is blown from a slit nozzle provided almost perpendicular to a running direction of a web, in a second of which a heat energy is imparted to the lower surface of a web, as a conduction heat, from a roll (heating roll) into which a heating medium such as steam and the like is supplied and in a third of which the first and second methods are combined.

In the planographic printing plate precursor of the invention, various known methods can be used in application of coating solutions on the lower layer and the image recording layer. Examples thereof include a roll coating method, a dip coating, an air knife coating method, a gravure coating method, a gravure offset coating, a hopper coating method, a blade coating method, a wire doctor coating method, a spray coating method and the like.

An upper coating method is desirably conducted in a non-contact fashion in order to prevent damage to a lower layer from being caused in coating an image recording layer. While a bar coater can be used as a method having been generally adopted in solvent type coating, though the bar coater works in a contact fashion, it is desirable to coat in a forward rotation driving in order to prevent damage to the lower layer.

In the planographic printing plate precursor of the invention, a coating amount of the lower layer is preferably in the range of from 0.1 to 5.0 g/m², more preferably in the range of from 0.2 to 2.0 g/m² and most preferably in the range of from 0.5 to 1.5 g/m² in weight after drying. If the coating amount is less than 0.1 g/m², it causes reduction in printing durability, while if the coating amount is more than 5.0 g/m², image reproducibility is degraded or sensitivity is decreased, both of which are unpreferable.

A coating amount of the image recording layer is preferably in the range of from 0.3 to 8.0 g/m² and more preferably in the range of from 0.4 to 2.0 g/m² in a weight after drying. As a coating amount decreases, an exposure amount for obtaining an image is smaller (high in sensitivity) at the expense of a film strength. As a coating amount increases, a film strength is improved, though with more of exposure amount and, for example, in the case of an actual use as a printing plate, a printing plate can be obtained with a possibility of a high number of sheets to be printed (a high printing durability).

Drying of the lower layer and the image recording layer coated on a support is usually conducted by heated air. Heating is preferably conducted at a temperature in the range of from 30° C. to 200° C. and more preferably in the range of from 40° C. to 140° C. A temperature during drying can be either kept at a constant value or raised stepwise. A case also arises where a good result is obtained by dehumidifying a drying air. A heated air is supplied onto a drying surface at a speed preferably in the range of from 0.1 m/sec to 30 m/sec and more preferably in the range of from 0.5 m/sec to 20 m/sec.

(Mat Layer)

It is preferable to provide a mat layer on a surface of the image recording layer having been provided as described above in order to shorten a time evacuating in contact exposure using a vacuum printing frame and to prevent a printing blur. The following methods are, specifically, exemplified: in one of which a mat layer is provided as described in JP-A No. 50-125805, JP-B Nos. 57-6582 and 61-28986, in a second of which solid powder is heat fused, which is described in JP-B No. 62-62337, and the like.

(Support)

A support used in the planographic printing plate precursor can be any of articles stable in terms of dimensions in the shape of a plate and no specific limitation is placed on a support and articles that have been used as a support of a printing plate can also be preferably used in the invention.

Examples of the support include paper and plastic (for example, polyethylene, polypropylene, polystyrene or the like) laminated paper; metal plates made of aluminum (including an aluminum alloy), zinc, iron, copper and the like; plastic films made of cellulose diacetate, cellulose triacetate, cellulose propionate, cellulose lactate, cellulose lactate acetate, cellulose nitrate, polyethylene terephthalate, polyethylene, polystyrene, polypropylene, polycarbonate, polyvinyl acetal and the like; paper or a plastic film laminated or evaporated with a metal as described above; and the like, and an aluminum plate is especially preferable. The aluminum plate includes a pure aluminum plate and an aluminum alloy plate. Various kinds of aluminum alloys can be used and examples thereof include aluminum alloys with metals such as silicon, copper, manganese, magnesium, chromium, zinc, lead, bismuth, nickel and the like. A composition of the support described above usually includes iron and titanium of some in content and other impurities of the order of a negligible value in content.

A support is surface treated if necessary. A hydrophilic treatment is preferably applied on a surface of a support of a planographic printing plate precursor of the invention. In the case of a support having a metal, especially aluminum surface, it is preferably to apply a surface treatment such as a graining treatment; a dipping treatment in an aqueous solution of sodium silicate, a potassium fluorozirconate, a phosphate; an anode oxidation treatment or the like. Furthermore, preferable examples of surface treated supports also include an aluminum plate applied with a graining treatment, followed by a dipping treatment in an aqueous solution of sodium silicate, as described in U.S. Pat. No. 2,714,066, and an aluminum plate subjected to an anode oxidation treatment, followed by a dipping treatment in an aqueous solution of an alkali metal silicate, as described in U.S. Pat. No. 3,181,461.

The anode oxidation treatment is implemented by causing a current to flow, with an aluminum plate as an anode, in an electrolytic solution made of an aqueous solution or solutions or a non-aqueous solution or solutions, in combination of two or more kinds thereof, of one or more kinds selected from the group consisting of, for example, inorganic acids such as phosphoric acid, chromic acid, sulfuric acid and boric acid; organic acids such as oxalic acid, sulfamic acid and the like; and salts thereof.

A silicate electroplating, which is described in U.S. Pat. No. 3,658,662, is useful. The hydrophilicization treatments is implemented in order to prevent a harmful reaction with a photosensitive composition provided on a support or to improve adhesion with an image recording layer in addition to the purpose to cause a surface of a support to be hydrophilic. A pretreatment on a surface of an aluminum plate may be applied in order to remove a rolling oil on the surface of the support or to expose a clean aluminum surface if necessary in advance of graining of the surface of an aluminum plate.

A solvent such as trichloroethylene, a surfactant or the like gas been used in order to cause the removal of a rolling oil. A method using an alkali etching agent such as sodium hydroxide, potassium hydroxide or the like have been widely used for the latter purpose to expose an aluminum surface.

Useful as methods of graining are mechanical, chemical and electrochemical methods. Examples of the mechanical method include a ball graining method, a blast graining method, a brushing graining method in which an aqueous dispersion slurry including a graining agent such as pumice is rubbed against a support with a nylon brush and the like; an example of the chemical method is suitably a method in which a support is immersed in a saturated aqueous solution of an aluminum salt in a mineral acid, which is described in JP-A No. 54-31187; and an example of the electrochemical method is preferably a method in which an AC electrolysis is effected in an acidic electrolyte including hydrochloric acid, a nitric acid or a mixed acid thereof. Among such surface roughening methods, a surface roughening method that is a combination of a mechanical surface roughening and electrochemical surface roughening is preferable because of a strong adhesion to a support of a photosensitive image, which is described in JP-A No. 55-137993. A graining treatment by means of a method described above preferably has a center line average height (Ra) as a surface roughness on a surface of an aluminum plate in the range of from 0.3 to 1.0 μm. An aluminum plate having been subjected to a graining treatment in such a way is washed with water and applied with a chemical etching, if necessary.

An etching treatment solution is usually selected from the group consisting of aqueous solutions of bases and acids dissolving aluminum. In this case, it is required not to form a film, different from aluminum, to be induced from an etching solution component on an etched surface. Examples of preferable etching agents include basic substances such as sodium hydroxide, pottasium hydroxide, trisodium phosphate, disodium phosphate, tripotassium phosphate, dipotassium phosphate and the like; and acidic substances such as sulfuric acid, persulfuric acid, phosphoric acid and, hydrochloric acid and salts thereof, wherein unpreferable are salts of metals lower in ionization than aluminum, for example zinc, chromium, cobalt, nickel, copper and the like because of formation of a film unnecessary for an etched surface. The etching agents are most preferably used in terms of conditions of a concentration and a temperature such that a dissolving speed of aluminum or an aluminum alloy in use is in the range of from 0.3 to 40 g/m² per one minute of an immersion time, while a dissolving speed can be higher or lower than the range without a trouble.

Etching is conducted in a way such that an aluminum plate is immersed in an etching solution described above or the etching solution is coated on the aluminum plate and the etching is preferably conducted so that an etching amount is in the range of from 0.5 to 10 g/m². As the etching agents, it is desirable to use an aqueous solution of a base because of a higher etching speed thereof as a characteristic. In this case, since a smut is formed, a desmut treatment is usually conducted. Examples of acids used in a desmut treatment include nitric acid, sulfuric acid, phophoric acid, chromic acid, hydrofluoric acid, borohydrofluoric acid and the like. An etched aluminum plate is washed with water and subjected to anodic oxidation, if necessary. The anodic oxidation can be conducted according to a method that has been conventionally adopted in the field of this technology.

Specifically, a film of anodic oxidation can be formed on a surface of an aluminum support by causing a DC or AC current to flow through aluminum in an aqueous solution or a non-aqueous solution including sulfuric acid, phophoric acid, chromic acid, oxalic acid, sulfamic acid or bezenesulfonic acid, or alternatively two or more kinds thereof in combination.

Since treatment conditions for anodic oxidation change in various ways according to kinds of electrolytic solutions in use, the conditions cannot be definitely determined, while proper treatment conditions are generally determined such that a concentration of an electrolytic solution is in the range of from 1 to 80% by weight, a temperature is in the range of from 5 to 70° C., a current density is in the range of from 0.5 to 60 A/dm², a voltage is in the range of from 1 to 100 V and an electrolysis time is in the range of from 30 sec to 50 min. For anodic oxidation in the conditions, preferable are a method of conducting anodic oxidation at a high current density in sulfuric acid, which is described in U.K. No. 1,412,768 and a method of conducting anodic oxidation in phosphoric acid as an electrolytic bath, which is described in U.S. Pat. No. 3,511,661. An aluminum plate subjected to surface roughening and anodic oxidation subsequent thereto as described above may be further applied with a hydrophilicization treatment, if necessary, preferable examples of which include methods of treating the aluminum plate with an aqueous solution of an alkali metal silicate, for example sodium silicate, as disclosed in U.S. Pat. Nos. 2,714,066 and 3,181,461; with an aqueous solution of potassium fluorozirconate disclosed in JP-B No. 36-22063; and with an aqueous solution of polyvinylphosphonic acid as disclosed in U.S. Pat. No. 4,153,461.

(Organic Undercoating Layer)

In a photosensitive planographic printing plate precursor of the invention, it is preferable to provide an organic undercoating layer before a lower layer is coated in order to reduce a residual film of a non-imaging portion. Examples of organic compounds used in such an organic undercoating layer include carboxymethyl cellulose, dextrin, gum arabic, phosphonic acids each having an amino group such as 2-aminoethylphosphonic acid; organic phosphonic acids each of which may have a substituent group such as phenyl phosphonic acid, naphthylphosphonic acid, an alkylphosphonic acid, glycerophosphonic acid, methylenediphosphonic acid, ethylenediphosphonic acid and the like; organic phosphoric acids each of which may have a substituent group such as phenylphosphoric acid, naphthylphosphoric acid, an alkylphosphoric acid, glycerophosphoric acid and the like; organic phosphinic acids each of which may have a substituent group such as phenylphosphinic acid, naphthylphosphinic acid, an alkylphosphinic acid, glycerophosphinic acid and the like; amino acids such as glycine, β-alanine and the like; and hydrochloric acid salts each of an amine having a hydroxyl group such as a hydrochloric acid salt of triethanol amine, which may be used in mixture of two or more kinds thereof.

It is preferable to add a compound having an onium group into an organic undercoating layer. Compounds each having an onium group are detailed in JP-A Nos. 2000-10292, 2000-108538 and the like.

In addition, it is possible to use at least one kind of a compound selected from the group consisting of polymeric compounds each having a structural unit represented by poly(p-vinylbenzoic acid) or the like in a molecule. More specific examples thereof include a copolymer between p-vinylbenzoic acid and vinylbenzyltriethyl ammonium salt, a copolymer between p-vinylbenzoic acid and vinylbenzyltrimethyl ammonium chloride and the like.

The organic undercoating layer can be provided according to one of methods as described below. That is, (i) a method is such that a solution obtained by dissolving an organic compound described above into water, an organic solvent such as methanol, ethanol, methyl ethyl ketone or the like, or a mixed solvent thereof is coated on a aluminum plate and the wet coat is dried and (ii) another method is such that an aluminum plate is immersed in a solution obtained by dissolving an organic compound described above into water, an organic solvent such as methanol, ethanol, methyl ethyl ketone or the like, or a mixed solvent thereof to cause the organic compound to be adsorbed onto the aluminum plate and thereafter the adsorbed organic compound thereon is washed with water and dried. In the method (i), a solution of the organic compound having a concentration in the range of from 0.005 to 10% by weight can be applied by means of one of various methods. Examples thereof include bar coater coating, rotation coating, spray coating, curtain coating and the like, any of which may be used. In the method (ii), a concentration of the solution is generally in the range of from 0.01 to 20% by weight and preferably in the range of from 0.05 to 5% by weight, an immersion temperature is generally in the range of from 20 to 90° C. and preferably in the range of from 25 to 50° C. and an immersion time is generally in the range of from 0.1 sec to 20 min and preferably in the range of from 2 sec to 1 min.

A pH value of a solution used in this case can also be used being adjusted to a value in the range of from 1 to 12 using a basic substance such as ammonia, triethylamine, potassium hydroxide or the like, or an acidic substance such as hydrochloric acid, phosphoric acid or the like. It is also possible to add a yellow dye into the solution for improving tone reproducibility of a planographic printing plate. Moreover, it is also possible to add a compound expressed by the following general formula (f) into the solution.

(HO)ₓ—R⁵—(COOH)_{y} General formula (f)

In the general formula (f), R⁵ represents arylene that may have a substituent group, which has 14 or less carbon atoms; x and y each represent an integer from 1 to 3 independently of each other. Specific examples of compounds expressed by the general formula (f) include 3-hydroxybenzoic acid, 4-hydroxybenzoic acid, salicylic acid, 1-hydroxy-2-naphtoic acid, 2-hydroxy-1-naphtoic acid, 2-hydroxy-3-naphtoic acid, 2,4-dihydroxybenzoic acid, 10-hydroxy-9-anthracene carboxylic acid and the like. A coating amount after drying of an organic undercoating layer is generally in the range of from 1 to 100 mg/m² and preferably in the range of from 2 to 70 mg/m². If the coating amount is less than 2 mg/m², no sufficient printing durability performance is obtained. If the coating amount is larger than 100 mg/m², a similar inconvenience occurs in this case.

(Back Coat)

A back coat is provided on a rear surface of a support, if necessary. Such back coats that are preferably used are a coating layer made of an organic polymeric compound described in JP-A No. 5-45885 and a coating layer made of a metal oxide obtained by hydrolyzing or polycoindensating an organic or inorganic metal compound described in JP-A No. 6-35174. Among the coating layers, especially preferable are alkoxy compounds of silicon such as Si(CH₃)₄, Si(OC₂H₅)₄, Si(OC₃H₇)₄, Si(OC₄H₉)₄ and the like because of easy availabiliy at a low cost and excellency in resistance to a developing solution of a metal oxide obtained therefrom.

A planographic printing plate precursor produced as described above is usually subjected to imagewise exposure and a developing treatment. A preferable light source of active light used in imagewise exposure is a light source having a light emission wavelength in the region from near infrared to infrared and especially preferable as a light source is a solid laser, that is a semiconductor laser.

A developing solution that can be adapted to a developing treatment for a planographic printing plate precursor of the invention preferably has a pH value generally in the range of from 9.0 to 14.0 and preferably in the range of from 12.0 to 13.5. A conventionally known alkali aqueous solution can be employed as a developing solution (a developing solution hereinafter includes a replenishing solution categorically). Examples of inorganic alkali salts include sodium silicate, potassium silicate, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium hydrogen carbonate, potassium hydrogen carbonate, ammonium hydrogen carbonate, sodium borate, potassium borate, ammonium borate, sodium hydroxide, ammonium hydroxide, potassium hydroxide, lithium hydroxide and the like. Examples of organic alkali substances include monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyrydine and the like. Aqueous solutions thereof may be used either alone or in combination of two or more kinds.

Among the alkali aqueous solutions, one of developing solutions by which the effect of the invention is exerted is an aqueous solution of a pH value of 12 or higher, referred to a so-called “silicate developing solution”, and including an alkali silicate as a base or an alkali silicate prepared by mixing a silicon compound into a base and another more preferable developing solution is a so-called “non-silicate developing solution” not containing alkali silicate while containing a non-reducing sugar (an organic compound with a buffer action) and a base.

In the former developing solution, a developability thereof of an alkali metal silicate aqueous solution can be adjusted by a ratio of silicon oxide SiO₂ and an alkali metal oxide M₂O, which are components of a silicate, (generally, expressed by a molar ratio of [SiO₂]/[M₂O]) and a concentrations of the silicate. Preferable examples thereof include an aqueous solution of sodium silicate, having a molar ratio of SiO₂/Na₂O in the range of from 1.0 to 1.5 (that is, [SiO₂]/[Na₂O]=1.0 to 1.5), and a content of SiO₂ in the range of from 1 to 4% by weight as disclosed in JP-A No. 54-62004 and an aqueous solution of an alkali metal silicate, having [SiO₂]/[M₂O] in the range of from 0.5 to 0.75 (that is, [SiO₂]/[M₂O]=1.0 to 1.5), having a concentration of SiO₂ in the range of from 1 to 4% by weight, and containing at least 20% of potassium with reference to gram atoms of all the alkali metal present in the developing solution.

A so-called “non-silicate developing solution” not containing an alkali silicate while containing a non-reducing sugar and a base is also preferably applied to development of a planographic printing plate precursor of the invention. A developing treatment of a planographic printing plate material using this developing solution does not degrade a surface of an image recording layer and can maintain thickness distribution of the image recording layer in a better condition.

It is preferable that this developing solution has main components including at least one compound selected from non-reducing sugars and at least one kind of a base, and a pH value the develop solution is in the range of from 9.0 to 13.5. Such reducing sugars are sugars having neither of free aldehyde and ketone groups and showing no reducing ability, and classified into a trehalose type oligosaccharide in which reducing groups are coupled with each other and a sugar alcohol obtained by hydrogenating a glycoside in each of which a reducing group of a sugar and a non-sugar are coupled with each other, and a sugar for reduction, each of which are preferably used. Trehalose type oligosaccharides are divided into sacchaloses and trehaloses and examples of glycosides include an alkyl glycoside, a phenol glycoside, a mustard oil glycoside and the like. Examples of sugar alcohols include D,L-arabit, ribit, xylit, D, L-sorbit, D, L-mannit, D, L-idit, D, L-talit, dulicit, allodulicit and the like. Furthermore, preferably exemplified are maltitol obtained by hydrogenating a disaccharide and a reduced product (reduced thick malt syrup) obtained by hydrogenating an oligosaccharide.

Among them, especially preferable reducing sugars are a sugar alcohol and a succharlose, and especially preferable are D-sorbit, sacchalose and reduced thick malt syrup because of having a buffer action in a proper pH region and a low cost.

The non-reducing sugars can be used either alone or in combination of two or more kinds and a proportion thereof in a developing solution is preferably in the range of from 0.1 to 30% by weight and more preferably in the range of from 1 to 20% by weight.

No sufficient buffer action is exerted at a proportion lower than the range while a higher concentration is hard to be obtained to result in a problem of cost increase. Note that in the case where a reducing sugar and a base is used in combination, a problem arises that a developing solution is discolored into brown, a pH value is gradually lowered and a developability is reduced over time in the case where a reducing sugar and a base are used in combination.

A conventionally known alkali substance can be used as a base used in combination with a non-reducing sugar. Examples of inorganic alkali substances include sodium hydroxide, potassium hydroxide, lithium hydroxxide, trisodium phosphate, tripotassium phosphate, triammonium phosphate, disodium phosphate, dipotassium phosphate, diammonium phosphate, sodium carbonate, potassium carbonate, ammonium carbonate, sodium hydrogen carbonate, potassium hydrogen carbonate, ammonium hydrogen carbonate, sodium borate, potassium borate, ammonium borate and the like. Examples of organic alkali substances include monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyrydine and the like.

The alkali substances may be used either alone or in combination of two or more kinds. Among them, preferable are sodium hydroxide and potassium hydroxide and the reason why is that pH adjustment can be done in a wider pH region by altering an amount of an alkali substanse relative to a non-reducing sugar. Furthermore, preferable are trisodium phophate, tripotassium phosphate, sodium carbonate, potassium carbonate and the like since each itself of them has a buffer action to be exerted.

An alkali substance described above is added into a developing solution so that a pH value of the developing solution is preferably in the range of 9.0 to 13.5 and more preferably in the range of from 10.0 to 13.2, though an additive amount of the alkali substance is determined by a desired pH value, and a kind and an additive amount of a reducing sugar.

Into the developing solution, it is possible to add an alkaline buffer solution including a weak acid other than a sugar and a strong base. As a weak acid used as a buffer solution, preferable is one having a dissociation constant (pKa) in the range of from 10.0 to 13.2.

Such a weak acid is selected from those described in “IONISATION CONSTANTS OF ORGANIC ACIDS IN AQUEOUS SOLUTION,” published by Pergamon Press Co., or the like and examples thereof include alcohols such as 2,2,3,3-tetrafluoropropanol-1 (pKa 12.74), trifluoroethanol (pKa 12.37), trichloroethanol (pKa 12.24) and the like; aldehydes such as pyrydine-2-aldehyde (pKa 12.68), pyridine-4-aldehyde (pKa 12.05) and the like; and compounds each having a phenolic hydroxyl group, such as salicylic acid (pKa 13.0), 3-hydroxy-2-naphtoic acid (pKa 12.84), catechol (pKa 12.6), gallic acid (pKa 12.4), sulfosalicylic acid (pKa 11.7), 3,4-dihydroxysulfonic acid (pKa 12.2), 3,4-dihydroxybenzoic acid (pKa 11.94), 1,2,4-trihydroxybenzene (pKa 11.82), hydroquinone (pKa 11.56), pyrogallol (pKa 11.34), o-cresol (pKa 10.33), resorcinol (pKa 11.27), p-cresol (pKa 10.27), m-cresol (pKa 10.09) and the like;

oximes such as 2-butanoneoxime (pKa 12.45), acetoxime (pKa 12.42), 1,2-cycloheptanedionedioxime (pKa 12.3), 2-hydroxybenzaldehydeoxime (pKa 12.10), dimethylglyoxime (pKa 11.9), ethanediamidedioxime (pKa 11.37), acetophenoneoxime (pKa 11.35) and the like; nucleic acid related substances such as adenosine (pKa 12.56), inosine (pKa 12.5), guanine (pKa 12.3), cytosine (pKa 12.2), hypoxanthine (pKa 12.1), xanthine (pKa 11.9) and the like; and other weak acids such as diethylaminomethylphophonic acid (pKa 12.32), 1-amino-3,3,3-trifluorobenzoic acid (pKa 12.29), isopropylidenephosphonic acid (pKa 12.10), 1,1-ethylydenediphophonic acid (pKa 11.54), 1,1-ethylidenediphosphonic acid 1-hydroxy (pKa 11.52), benzimidazole (pKa 12.86), thiobenzamide (pKa 12.8), pycolinethioamide (pKa 12.55), barbituric acid (pKa 12.5) and the like.

Among the weak acids, preferable are sulfosalycilic acid and salicylic acid. As bases used in combination with the weak acids, preferable are sodium hydroxide, ammonium hydroxide, potassium hydroxide and lithium hydroxide. The alkali substances are used either alone or in combination of two or more kinds. A pH value is adjusted in a preferable range by a concentration of an alkali substance or combination of alkali substances in use.

Into a developing solution, it is possible to add various kinds of surfactants and various kinds of organic solvents if necessary for the purpose to promote developability, to facilitate dispersion of development sediment and to enhance an inkphilicity of a printing plate imaging portion. Examples of preferable surfactants include an anionic surfactant, a cationic surfactant, a nonionic surfactant and an ampholytic surfactant.

Preferable examples of surfactants include nonionic surfactants such as poluoxyethylenealkyl ethers, polyoxyethylenealkyl phenyl ethers, polyoxyethylenepolystyryl phenyl ethers, polyoxyethylenepolyoxypropylenealkyl ethers, glycerin fatty acid partial esters, solbitan fatty acid partial esters, pentaerythritol fatty acid partial esters, propyleneglycol monofatty acid esters, saccharose fatty acid partial esters, polyoxyethylenesorbitan fatty acid partial esters, polyoxyethylenesorbitol fatty acid partial esters, polyethyleneglycol fatty acid esters, polygrycerin fatty acid partial esters, polyoxyethylenized caster oils, polyoxyethylenegrycerin fatty acid partial esters, fatty acid diethanolamides, N,N-bis-2-hydroxyalkylamines, polyoxyethylenealkylamines, triethanolamine fatty acid esters, trialkylamine oxides and the like;

anionic surfactants such as fatty acid salts, abietic acid salts, hydroxyalkanesulfonic acid salts, alkanesulfonic acid salts, dialkylsulfosuccinate ester salts, linear chain alkylbenzenesulfonic acid salts, branched chain alkylbenzenesulfonic acid salts, alkylnaphthalenesulfonic acid salts, alkylphenoxypolyoxyethylenepropylsulfonuic acid salts, polyoxyethylenealkylsulfophenyl ether salts, N-methy-N-oleyltaurin sodium salt, N-alkylsulfosuccinic monoamide disodium salt, petroleumsulfonic acid salts, sulfated beef tallow oil, sulfate ester salts of fatty acid alkyl esters, alkylsulfate ester salts polyoxyethylenealkyl ether sulfate ester salts, fatty acid monoglyceride sulfate ester salts, polyoxyethylenealkylphenyl ether sulfate ester salts, polyoxyethylenestyrylphenyl ether sulfate ester salts, alkylphosphate ester salts, polyoxyethylenealkyl ether phosphate ester salts, polyoxyethylenealkyl phenyl ether phosphate ester salts, partial saponified substanses of styrene/maleic anhydride copolymer, partial saponified substances of olefin/maleic anhydride copolymer and nathalenesulfonic acid salt formalin condensates and the like; cationic surfactants such as quaternary ammonium salts including alkylamine salts, tetrabutylammonium bromide and the like, polyoxyethylenealkylamine salts, polyethylenepolyamine derivatives and the like; and ampholytic surfactants such as carboxybetaines, aminocarboxyl acids, sulfobetaines, aminosulfate esters, imidazolines and the like. Among the surfactants described above, part of a name of a surfactant “polyoxyethylene” can be replaced with one part selected from the group consisting of polyoxyalkylenes such as polyoxymethylene, polyoxypropylene, polyoxybutylene and the like, surfactants corresponding to which are also included in the surfactants of the invention.

A more preferable surfactant is a fluorine containing surfactant containing a perfluoroalkyl group in a molecule. Examples of fluorine containing surfactant include anionic surfactants such as perfluoroalkylcarboxylic acid salts, perfluoroalkylsulfonic acid salts, perfluoroalkylphosphate esters; ampholytic surfactants such as perfluoroalkylbetaines and the like; cationic surfactants such as perfluoroalkyltrimethyl ammonim salts and the like; and nonionic surfactants such as perfluoroalkylamine oxides, perfluoroalkylethylene oxide adducts, oligomers each containing a perfluoroalkyl group and a hydrophilic group, oligomers each containing a perfluoroalkyl group and a lipophilic group, oligomers each containing a perfluoroalkyl group, a hydrophillic group and a lipophilic group, urethanes each containing a perfluoroalkyl group and a lipophilic group and the like. The surfactants can be used either alone or in combination of two or more kinds, and one or more thereof combined are added into a developing solution preferably in the range of from 0.001 to 10% by weight and more preferably in the range of from 0.01 to 5% by weight.

Various kinds of development stabilizers can be added into a developing solution. Preferable examples thereof include tetraalkyl ammonium salts such as a polyethyleneglycol adduct of a sugar alcohol, tetrabutyl ammonium hydroxide described in JP-A No. 6-282079; phosphonium salts such as tetrabutyl phosphonium bromide and the like; and iodonium salts such as diphenyl iodonium chlorides and the like. Another examples thereof include anionic surfactants or ampholytic surfactants described in JP-A No. 50-51324; water-soluble cationic polymers described in JP-A No. 55-95946; and water-soluble ampholytic polymer electrolytes described in JP-A No. 56-142528.

Further examples thereof include organic boron compounds each added with an alkylene glycol described in JP-A No. 59-84241; water-soluble surfactants each of a polyoxyethylene-polyoxypropylene block polymerization type described in JP-A No. 60-111246; alkylenediamine compounds substituting in polyoxyethylene-polyoxypropylene described in JP-A No. 60-129750; polyethylene glycols each having a weight average molecular weight of 300 or more described in JP-A No. 61-215554; fluorine containing surfactants each having a cationic group described in JP-A No. 63-175858; and water-soluble ethylene oxide adducts obtained by adding 4 or more mol of ethylene oxide to 1 mol of an acid or an alcohol, water-soluble polyalkylene compounds and the like described in JP-A No. 2-39157.

An organic solvent is added into a developing solution if necessary. As such an organic solvent, preferable is an organic solvent having a solubility in water of about 10% by weight or less and more preferable is an organic solvent having a solubility in water of 5% by weight or less. Examples thereof include 1-phenylethanol, 2-phenylethanol, 3-phenyl-1-propanol, 4-phenyl-1-butanol, 4-phenyl-2-butanol, 2-phenyl-1-butanol, 2-phenoxyethanol, 2-benzyloxyethanol, o-methoxybenzyl alcohol, m-methoxybenzyl alcohol, p-methoxybenzyl alcohol, benzyl alcohol, cyclohexanol, 2-methylcyclohexanol, 3-methylcyclohexanol and 4-methylcyclohexanol, N-phenylethanolamine, N-phenyldiethanolamine and the like.

A content of an organic solvent is in the range of from 0.1 to 5% by weight relative to all the weight of a solution in use. An amount in use thereof is in a close relation with an amount in use of a surfactant, and with an increase in amount of the organic solvent, an amount in use of the surfactant is preferably increased. This is because if an amount of a surfactant is less while an amount of an organic solvent is more, the organic solvent is not fully dissolved, thereby disabling securement of good developability to be expected.

A reducing agent can be further added Into a developing solution. This is to prevent staining on a printing plate from occurring. Examples of preferable organic reducing agents include phenol compounds such as thiosalicylic acid, hydroquinone, methol, methoxyquinone, resolcin, 2-methylresolcine and the like; and amine compounds such as phenylenediamine, phenylhydrazine and the like. Examples of preferable inorganic reducing agents include sodium salts, potassium salts and ammonium salts of inorganic acids such as sulfurous acid, hydrogen sulfurous acid, phosphorous acid, hydrogen phosphorous acid, dihydrogen phosphorous acid, thiosulfuric acid, and dithionous acid.

Among them, sulfites are especially excellent in staining preventive effect. A reducing agent described above is contained preferably in the range of from 0.05 to 5% by weight relative to a developing solution in use.

An organic carboxylic acid can also be further added into a developing solution. Preferable organic carboxylic acids are an aliphatic carboxylic acid having 6 to 20 carbon atoms and an aromatic carboxylic acid. Specific examples of aliphatic carboxylic acids include capronic acid, enanthylic acid, caprylic acid, laulylic acid, myrystic acid, palmitic acid, stearic acid and the like, and especially preferable is an alkanoic acid having 8 to 12 carbon atoms. An aliphatic carboxylic acid may be either an unsaturated aliphatic acid having a double bond in carbon chan or an aliphatic carboxylic acid having a branched chain. Examples of aromatic carboxylic acids include compounds obtained by substituting a carboxylic group at a position on each of a benzene ring, a naphthalene ring, an anthracene ring and the like, which specifically include o-chlorobenzoic acid, p-chlorobenzoic acid, o-hydroxybenzoic acid, p-hydroxybenzoic acid, o-aminobenzoic acid, p-aminobenzoic acid, 2,4-dihydrobenzoic acid, 2,5-dihydrobenzoic acid, 2,6-dihydroxybenzoic acid, 2,3-dihydroxybenzoic acid, 3,5-dihydroxybenzoic acid, gallic acid, 1-hydroxy-2-naphthoic acid, 3-hydroxy-2-naphthoic acid, 2-hydroxy-1-naphthoic acid, 1-naphthoic acid, 2-naphthoic acid and the like, among which hydronaphthoic acid is especially effective.

An aliphatic carboxylic acid or aromatic carboxylic acid described above is preferably used as any of sodium salt, a potassium salt and an ammonium salt in order to raise a solubility in water. No specific limitation is placed on a content of an organic carboxylic acid in a developing solution used in the invention, while if the content is less than 0.1% by weight, an effect is insufficient, while if the content is 10% by weight or more, no more of improvement on the effect is obtained and in addition, a different additive, when added, dissolution thereof has a chance to be inhibited. Accordingly, an additive amount thereof is preferably in the range of from 0.1 to 10% by weight and more preferably in the range of from 0.5 to 4% by weight relative to a developing agent in use.

Into a developing solution, it is also possible to add an anticeptic agent, a coloring agent, a thickner, a defoaming agent, a water softener and the like. Examples of water sofeners include polyphosphric acid, and a sodium salt, potassium salts and ammonium salts thereof; aminocarboxylic acids such as ethylenediaminetetraacetic acid, diethylenetriaminepentaacetic acid, triethylenetetraaminehexaacetic acid, hydroxyethylethylenediaminetriacetic acid, nitrotriacetic acid, 1,2-diaminocyclohexanetetraacetic acid and 1,3-diamino-2-propanoltetraacetic acid and the like, and sodium salts, potassium salts and ammonium salts thereof; aminotri(methylenephosphonic acid), ethylenediaminetetra(methylenephosphonic acid), diethylenetriaminepenta(methylenephosphonic acid), triethylenetetraaminehexa(methylenephosphonic acid), hydroxyethylethylenediaminetri(methylenephosphonic acid) and 1-hydroxyethane-1,1-diphoshonic acid and sodium salts, potassium salts and ammonium salts thereof.

An optimal content of a water softener as described above is changed by chelation thereof, a hardness of hard water in use and an amount of the hard water, while a content thereof is generally in the range of from 0.01 to 5% by weight relative to a developing solution in use and preferably in the range of from 0.01 to 0.5% by weight. If the content is less than the range, a desired object is not sufficiently achieved, while the content is exceed the range, a wrong influence such as decoloring or the like occurs on an imaging portion. The balance of the developing solution is water. The developing solution is stored as a concentrated solution containing less water than when it is used and diluted with water when it is used, which is advantageous in terms of transportation. A degree of concentration is properly determined such that components are not separated or precipitated.

A developing solution described in JP-A No. 6-282079 can also be used as a developing solution for a planographic printing plate precursor of the invention. The developing solution contains an alkali metal silicate salt that has a molar ratio of SiO₂/M₂O (wherein M represents an alkali metal) in the range of from 0.5 to 2.0, and a water-soluble ethylene oxide adduct obtained by adding 5 or more mol of ethylene oxide to a sugar alcohol having 4 or more hydroxyl groups. A sugar alcohol is a polyvalent alcohol obtained by reducing an aldehyde group and a ketone group of sugar into a first alcohol and a second alcohol, respectively. Specific examples of sugar alcohols include D, L-threit, erythrit, D,L-arabit, ribit, xylit, D, L-sorbit, D, L-mannit, D, L-idit, D, L-talit, dulicit, allodulicit and the like, and in addition, di-, tri, tetra-, penta-, and hexaglycerins obtained by condensing of sugar alcohols, and the like. A water-soluble ethylene oxide adduct described above is obtained by adding 5 or more mol of ethylene oxide to 1 mol of the sugar alcohol. An ethylene oxide adduct may be block copolymerized with propylene oxide in a range in which a solubility of a product can be allowed if necessary. Ethylene oxide adducts may be used either alone or in combination of two or more kinds.

An additive amount of an aqueous ethylene oxide adduct is preferably in the range of from 0.001 to 5% by weight and more preferably in the range of from 0.001 to 2% by weight relative to a developing solution in use.

Into a developing solution, it is possible to add the various kinds of surfactants and the various kinds of organic solvents if necessary for the purpose to promote a developability, to facilitate dispersion of development sediment and to enhance an inkphilicity of a printing plate imaging portion.

A photosensitive planographic printing plate precursor applied with a developing treatment using a developing solution of the composition is subjected to a post treatment using washing water, a rinse solution containing a surfactant and the like, a finisher containing gum arabic, a starch derivative and the like as main components and a protective gum solution. In a post treatment for a planographic printing plate precursor of the invention, the treatments can be used in combination in various ways.

In recent years, in the plate and printing industries, an automatic developing machine for a photosensitized plate has been widely used for rationalization and standardization of a printing plate making operation. The automatic developing machine is generally constituted of a developing section, a post treatment section, an apparatus transporting a photosensitized plate, treatment solution baths and a spray apparatus, wherein a photosensitized plate after exposure is transported horizontally and in this state, treatment solutions pumped up are blown to the plate from spray nozzles to thus conduct development and a post treatment. Very recently, there have been known automatic treatment methods, in one of which a photosensitized plate is immersion transported by in-liquid guide rolls within a treatment solution bath filled with the treatment solution to develop the plate, and in the other of which a small constant amount of washing water is supplied on a surface of a presensitive plate after development and wastewater is recycled as diluting water for a developing solution.

In such an automatic treatment, treatment can be carried out while replenishing solutions are supplied to respective treatment solutions, each according to a treatment amount and an operation time thereof and the like. A so-called single-use treatment scheme can be applied, in which a treatment is implemented with a substantially unused treatment solution. A planographic printing plate obtained in such treatments is loaded on an offset press to carry out printing on multiple sheets.

### EXAMPLES

Below, examples will be given to more concretely describe the present invention. However, it should be understood that the invention is not limited thereto.

(Preparation of Support)

Supports A, B, C and D were prepared through a combination of steps described below using a JIS-A-1050 aluminum plate of 0.3 mm thickness.

(a) Mechanical Surface Roughening Treatment

A suspension of a graining agent (quartz sand) having a specific gravity of 1.12 in water was continuously supplied onto a surface of the aluminum plate as a graining slurry liquid, in parallel to which mechanical surface roughening was conducted using a rotary roller nylon brush. An average particle diameter of the graining agent was 8 μm and the maximum particle diameter thereof was 50 μm. Bristles of the nylon brush were each made of 6·10 nylon, 50 mm in length and 0.3 mm in diameter. The bristles were densely implanted in holes formed on an outer surface of a stainless cylinder of φ300 mm in diameter. Three rotary brushes were employed. Two brushes (φ200 mm in diameter) were positioned at the lower side as support roller brushes so as to be separated from each other by a distance of 300 mm. The top brush roller was pressed against the aluminum plate in graining so that a load during graining increased by 7 kW relative to a load prior to the graining. A rotational direction of the top roller brush at the contact portion with the aluminum plate was the same as a moving direction of the aluminum plate. A rotational speed of the top brush was 200 rpm.

(b) Alkali Etching Treatment

An etching treatment was conducting by spraying a NaOH aqueous solution (having a NaOH concentration of 26% by weight and an aluminum ion concentration of 6.5% by weight) at a temperature of 70° C. onto the aluminum plate obtained in the above process, to dissolve 6 g/m² of the aluminum therefrom. Thereafter, the aluminum plate was spray washed with well-water.

(c) Desmut Treatment

A desmut treatment was conducted by spraying a 1% by weight nitric acid aqueous solution (including aluminum ions at a concentration of 0.5% by weight) at a temperature of 30° C., followed by spray washing with water. The nitric acid aqueous solution used in the desmut treatment was a waste solution from a process in which electrochemical surface roughening was performed using an AC current in a nitric acid aqueous solution.

(d) Electrochemical Surface Roughening Treatment

An electrochemical surface roughening treatment was continuously conducted using an AC voltage of 60 Hz. An electrolytic solution used at this time was a 10.5 g/l nitric acid aqueous solution (containing aluminum ions at a concentration of 5 g/l) at a temperature of 50° C. The electrochemical surface roughening treatment was conducted under the conditions such that an AC power supply waveform was in the shape of a trapizoid classified as a rectangular alternate current with a time TP from a current value of 0 until the value reached a peak of 0.8 msec, and a DUTY ratio of 1:1, and a carbon electrode was used as an opposite electrode. An auxiliary electrode was made of ferrite. An electrolytic cell was of a radial cell type.

A current density was 30 A/dm², at a peak and an electricity amount was 220 C/dm² in a total amount thereof when the aluminum plate worked as an anode. A amount of 5% of a current flowing out from a power supply was shunted into the auxiliary anode. After the treatment, the aluminum plate was spray washed with well-water.

(e) Alkali Etching Treatment

Etching was conducted on the aluminum plate by spraying an etching solution having a caustic soda concentration of 26% by weight and an aluminum ion concentration of 6.5% by weight at 32° C., to dissolve 0.20 g/m² the aluminum plate and to remove a smut component having aluminum hydroxide as a main component generated in electrochemical surface roughening using an alternate current at the previous stage, and in addition, to dissolve an edge portion of each pit generated to a smooth profile. Thereafter, the aluminum plate was spray washed with well-water.

(f) Desmut Treatment

A desmut treatment was conducted by spraying with a 15% by weight sulfuric acid aqueous solution (including an aluminum ion concentration of 4.5% by weight) at a temperature of 30° C., followed by spray washing with well-water. The nitric acid aqueous solution used in the desmut treatment was a waste solution from a process in which electrochemical surface roughening was performed using an AC current in a nitric acid aqueous solution.

(g) Electrochemical Surface Roughening Treatment

An electrochemical surface roughening treatment was continuously conducted using an AC voltage of 60 Hz. An electrolytic solution used at this time was a 7.5 g/l hydrochloric acid aqueous solution (containing aluminum ions at a concentration of 5 g/l) at a temperature of 35° C. The electrochemical surface roughening treatment was conducted under conditions such that an AC power supply waveform was a rectangular waveform and a carbon electrode was used as an opposite electrode. An auxiliary electrode was made of ferrite. An electrolytic cell was of a radial cell type.

A current density was 25 A/dm² at a peak, and an electricity amount was 50 C/dm² in a total amount thereof when the aluminum plate worked as an anode. After the treatment, the aluminum plate was spray washed with well-water.

(h) Alkali Etching Treatment

Etching was conducted on the aluminum plate by spraying an etching solution having a caustic soda concentration of 26% by weight and an aluminum ion concentration of 6.5% by weight at 32° C. to dissolve 0.10 g/m² of the aluminum plate and to remove a smut component having aluminum hydroxide as a main component generated in electrochemical surface roughening using an alternate current at the previous stage, and in addition, to dissolve an edge portion of each pit generated to a smooth profile. Thereafter, the aluminum plate was spray washed with well-water.

(i) Desmut Treatment

A desmut treatment was conducted by spraying with a 25% by weight sulfuric acid aqueous solution (including aluminum ions concentration of 0.5% by weight) at a temperature of 60° C., followed by spray washing with well-water.

(j) Anodic Oxidation Treatment

A sulfuric acid was used as an electrolytic solution. The electrolytic solution in each case was at a sulfuric acid concentration of 170 g/l (including aluminum ions of 0.5% by weight) and at a temperature of 43° C., followed by spray washing with well-water.

A current density in each case was about 30 A/dm². A final oxide film amount was 2.7 g/m².

<Support A>

A support A was prepared by conducting the steps (a) to (j), wherein an etching amount in the step (e) was 3.4 g/m².

<Support B>

A support B was prepared by sequentially conducting the steps omitting the steps (g) to (i).

<Support C>

A support C was prepared by sequentially conducting the steps omitting the steps (a) and (g) to (i).

<Support D>

A support D was prepared by sequentially conducting the steps omitting the steps (a) and (d) to (f), wherein a total amount of electricity in the step (g) was 450 C/dm².

The supports A to D having been obtained as described above was subjected to the following hydrophilicization treatment and undercoating treatment subsequent to the above process.

(k) Alkali Metal Silicate Treatment

An aluminum support having been obtained in the anodic oxidation treatment was immersed in a treatment bath filled with a 1% by weight aqueous solution of No. 3 sodium silicate at a temperature of 30° C. for 10 sec to thereby effect an alkali metal silicate treatment (silicate treatment). Thereafter, spray washing was conducted with well-water. An amount of silicate at this time was 3.6 mg/m².

[(1) Formation of Undercoating]

An undercoating solution having been obtained was applied on the aluminum support obtained upon completion of the above-described alkali metal silicate treatment, followed by drying at 80° C. for 15 sec. A coating amount after the drying was 18 mg/m².

<Composition of Undercoating Solution>

| | |
|---|---|
| the following polymeric compound | 0.3 g |
| methanol | 100 g |
| water | 1.0 g |

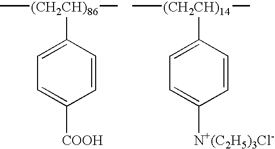

Weight average molecular weight 20,000

### Examples 1 to 7

A first layer (lower layer) coating solution with the following composition was applied on an obtained support, and thereafter the wet coat was dried in a drying oven at 150° C. for 60 seconds to obtain a coating amount of 0.85 g/m².

An image recording layer (upper layer) coating solution with the following composition was applied, by a wire bar coater, on the obtained support having the lower layer. After application, the wet coat was dried in a drying oven at 145° C. for 70 seconds to obtain a positive planographic printing plate precursor with a total coating amount of 1.1 g/m².

<First Layer (Lower Layer) Coating Solution>

copolymer of N-(p-aminosulfonylphenyl)metacyrilamid with methyl methacrylate and acrylonitril 2.133 g (with a molar ratio of 37:33:30 and a weight average molecular weight of 59,000 and containing 0.6% by weight of N-(p-aminosulfonylphenyl)metacyrilamid as a non-reacted monomer)

| | |
|---|---|
| cyanine dye A (with the following structure) | 0.098 g |
| 2-mercapt-5-methylthio-1,3,4-thiazole | 0.030 g |
| cis-Δ⁴-tetrahydrophthalic anhydride | 0.100 g |
| 4,4′-sulfonyldiphenyl | 0.090 g |
| p-toluenesulfonic acid | 0.008 g |
| ethyl violet with a counter anion thereof | 0.100 g |
| replaced with 6-hydroxynaphthalenesulfonic acid | |
| 3-methoxy-4-diazodiphenylaminehexafluorophophate | 0.030 g |
| fluorine containing surfactant (the following | 0.035 g |
| polymer 1) | |
| methyl ethyl ketone | 26.6 g |
| 1-methoxy-2-propanol | 13.6 g |
| γ-butyrolactone | 13.8 g |

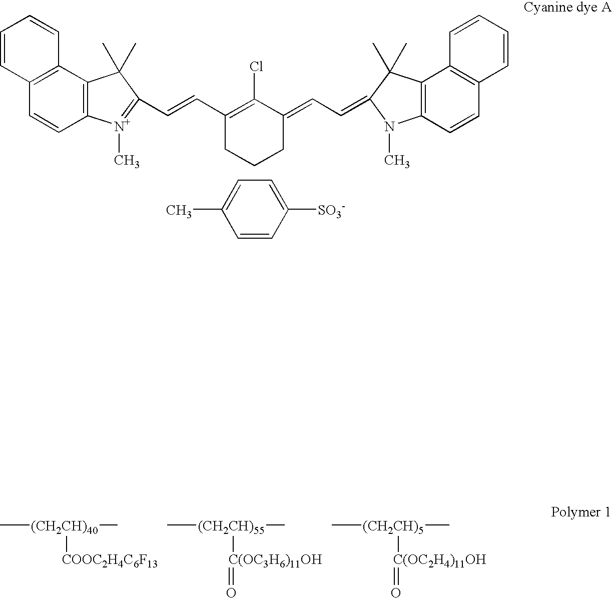

<Image Recording Layer (Upper Layer) Coating Solution>

| | |
|---|---|
| copolymer of ethyl methacrylate with | 0.042 g |
| 2-methacryloyloxyethylsuccinic acid (with a molar | |
| ratio of 67:33 and a weight average molecular | |
| weight of 110,000) | |
| a phenol containing novolak resin described in | 0.348 g |
| the following Table 1 | |
| cyanine dye A (with the following structure) | 0.0115 g |
| cyanine dye B (with the following structure) | 0.0077 g |
| 5-benzoyl-4-hydroxy-2-methoxybenzenesulfonic acid | 0.004 g |
| salt of 1-(4-methylbenzyl)-1-phenylpiperidinium | |
| fluorine containing surfactant (the above polymer 1) | 0.015 g |
| fluorine containing surfactant (the following | 0.003 g |
| polymer 2) | |
| methyl ethyl ketone | 13.1 g |
| 1-methoxy-2-propanol | 6.79 g |

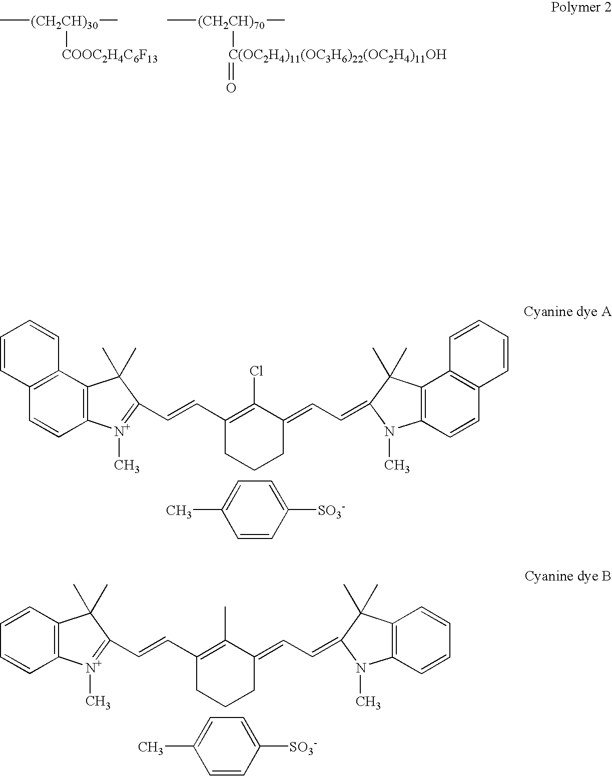

### Comparative Example 1

A planographic printing plate precursor of Comparative Example 1 was obtained in the same manner as in Examples 1 to 7 except that a cresol novolak resin containing no phenol as a structural unit (with a compositional ratio of m-cresol/p-cresol=50/50) was used instead of the phenol containing novolak resin of the present invention.

[Evaluation of Photosensitive Planographic Printing Plate]

[Evaluation of Development Latitude]

An obtained photosensitive planographic printing plate was stored for 5 days under conditions of a temperature of 25° C. and a relative humidity of 50% RH, followed by imagewise writing of a test pattern on the plate using a Trendsetter 3244VX manufactured by Creo Inc. under conditions of a beam intensity of 9.0 W and a drum rotation speed of 150 rpm.

Thereafter, alkali developing solutions were prepared by altering water amounts in alkali developing solutions having the following compositions A and B at various dilution ratios to alter conductivity values of the alkali developing solutions for actual use, and the prepared alkali developing solutions with various conductivity values were each fed into a PS-processor-900H manufactured by Fuji Photo Film Co., Ltd. to conduct development for 22 sec while maintaining a temperature of the developing solution at 30° C. At this time, evaluation was carried out defining development latitude as a difference between the highest conductivity value and the lowest conductivity value among conductivity values of developing solutions in which an image area was not eluted, and in which development was well effected without staining and coloring being caused by a residual film of an image recording layer where development is defective. The larger this difference is, the more excellent the development latitude is evaluated to be. Results are shown in the following Table 1.

<Composition of Alkali Developing Solution A>

| | |
|---|---|
| SiO₂.K₂O (SiO₂.K₂O = 1/1 in molar ratio) | 4.0% by weight |
| citric acid | 0.5% by weight |
| polyethylene glycol lauryl ether | 0.5% by weight |
| (with a weight average molecular weight of 1,000) | |
| water | 95.0% by weight |

<Composition of Alkali Developing Solution B>

| | |
|---|---|
| D-sorbit | 2.5% by weight |
| sodium hydroxide | 0.85% by weight |
| polyethylene glycol lauryl ether | 0.5% by weight |
| (with a weight average molecular weight of 1,000) | |
| water | 96.15% by weight |

[Sensitivity]

A test pattern was imagewise written on an obtained planographic printing plate precursor altering exposure energy with a Trendsetter 3244VX manufactured by Creo Inc. Thereafter, the printing plate precursor was developed with an alkali developing solution having a conductivity value at an intermediate point (an average value) between the highest and lowest values of the developing solutions which were used in the above evaluation of development latitude, in which an image area was not eluted, and in which development was well effected without staining and coloring being caused by a residual film of an image recording layer where development was defective, and an exposure amount (a beam intensity when a drum rotation speed is 150 rpm) at which a non-imaging area could be developed was measured and used as a sensitivity. The smaller the value was, the higher the sensitivity was evaluated to be.

[Printing Durability]

A test pattern was imagewise written on each of the planographic printing plate precursors obtained in Examples 1 to 7 and Comparative Example 1 altering exposure energy with a Trendsetter 3244VX manufactured by Creo Inc. Thereafter, using a PS-processor 900H manufactured by Fuji Photo Film Co., Ltd. into which a developing solution having the composition B was fed, development was conducted under conditions of a development temperature of 30° C. and a development time of 12 seconds. Continuous printing was conducted using the developed plates in a printing machine with a trade name Lithrone manufactured by Komori Corporation. During the printing, the number of sheets that were printed with a sufficient ink concentration measured by visual inspection to thereby evaluate printing durability of a printing plate. The greater the number of sheets printed was, the more excellent printing was evaluated to be.

[Chemical Resistance]

Printing was conducted in the same manner as in evaluation of the printing durability. In this evaluation of chemical resistance, a step was added to the process, in which step a surface of a printing plate was wiped with a cleaner (with a trade name of Multicleaner manufactured by Fuji Photo Film Co., Ltd.) with respect to each 5,000 sheets printed. The greater the number of sheets printed was, the more excellent chemical resistance was evaluated to be.

Evaluation results are shown in the following Table 1.

TABLE 1

| | | Novlak resin | | Development latitude | | | | | |
|---|---|---|---|---|---|---|---|---|---|
| | | Compositional | Weight | (mS/cm) | | Sensitivity (W) | | Printing | Chemical |
| | | ratio (phenol/ | average | Developing | Developing | Developing | Developing | durability | resistance |
| | | m-cresol/ | molecular | solution | solution | solution | solution | (in 10,000 | (× 10,000 |
| | Support | p-cresol) | weight | A | B | A | B | sheets) | sheets) |
| Example 1 | A | 70/30/0 | 6500 | 6 | 7 | 5 | 5 | 22 | 20 |
| Example 2 | B | 70/30/0 | 6500 | 5 | 6 | 5 | 5.5 | 22 | 21 |
| Example 3 | C | 70/30/0 | 6500 | 6 | 6 | 5 | 5 | 25 | 22 |
| Example 4 | D | 70/30/0 | 6500 | 6 | 6 | 5.5 | 5 | 23 | 20 |
| Example 5 | D | 20/40/40 | 5000 | 6 | 6 | 5.5 | 5.5 | 25 | 22 |
| Example 6 | A | 50/30/20 | 5500 | 6 | 6 | 5.5 | 6 | 21 | 19 |
| Example 7 | A | 50/40/10 | 5500 | 6 | 6 | 5.5 | 6 | 22 | 19 |
| Comparative | A | 0/50/50 | 4500 | 4 | 4 | 6.5 | 6.5 | 20 | 15 |
| example 1 | | | | | | | | | |

As is clearly shown in table 1, the planographic printing plate precursor of the invention was able to record at a higher sensitivity and was more excellent in development latitude, printing durability and chemical resistance in comparison with Comparative Example 1 in which a cresol novolak resin including no phenol as a structural unit was used in an image recording layer.

### Example 8 and Comparative Example 2

The following image recording layer coating solution 2 was applied on the obtained support A and the wet coat was dried in an oven at 150° C. for 1 minute to prepare a planographic printing plate precursor of Comparative Example 2 having a positive image recording layer with 1.8 g/m² of a coating amount after drying.

<Image Recording Layer Coating Solution 2>

| | |
|---|---|
| copolymer of ethyl methacrylate with 2-methacryloyloxy- | 0.042 g |
| ethylsuccinic acid (with a molar ratio = 67:33 and a | |
| weight average molecular weight of 110,000) | |
| a phenol containing m,p-cresol novolak | 0.94 g |
| (with a Ph/m/p ratio = 5/3/2 a mass-average molecular | |
| weight of 5,500, and containing 0.5% by weight of a | |
| non-reacted cresol) | |
| copolymer of n-butyl methacrylate with methacrylic acid | 0.06 g |
| (with a molar ratio of 73:27 and a mass-average | |
| molecular weight of 51,000) | |
| light-to-heat conversion agent (the cyanine dye A) | 0.03 g |
| light-to-heat conversion agent (the cyanine dye B) | 0.01 g |
| 2,4,6-tris(hexyloxy)benzenediazonium-2-hydroxy-4- | 0.01 g |
| methoxybenzophenone-5-sulfonate | |
| p-toluenesulfonic acid | 0.002 g |
| dye, victoria pure blue BOH with a 1-naphthalenesuslfonic | 0.015 g |
| anion as a counter anion | |
| fluorine containing surfactant | 0.02 g |
| (with a trade name of MEGAFAC F-780 manufactured by | |
| Dainippon Ink and Chemicals Incorporated) | |
| methyl ethyl ketone | 17 g |
| 1-methoxy-2-propanol | 5 g |

[Evaluation of Development Latitude and Printing Durability]

Exposure and development were conducted on an obtained planographic printing plate precursor in the same manner as in Examples 1 to 7 except for that a developing solution was replaced with a developing solution obtained by dilution of the development solution DT-2 manufactured by Fuji Photo Film Co., Ltd. and a development time is changed to 14 seconds, and evaluation of development latitude, sensitivity, printing durability and chemical resistance was conducted. Results are shown in Table 2. Furthermore, as a reference example, evaluation was conducted with respect to Example 8 having an image recording layer of a layered structure using a specific novolak resin identical to that of Comparative Example 2.

TABLE 2

| | | | | Development | | | |
|---|---|---|---|---|---|---|---|
| | | Novlak resin | | latitude | | | |
| | | Compositional | Weight | (mS/cm) | Sensitivity (W) | Printing | Chemical |
| | | ratio | average | Developing | Developing | durability | resistance |
| | | (phenol/m-cresol/ | molecular | solution | solution | (× 10,000 | (× 10,000 |
| | Support | p-cresol) | weight | DT-2 | DT-2 | sheets) | sheets) |
| Example 8 | A | 50/30/20 | 5500 | 6.5 | 5.0 | 23 | 20 |
| Comparative | A | 50/30/20 | 5500 | 6.0 | 5.0 | 21 | 16 |
| example 2 | | | | | | | |

As is clearly shown in Table 2, the planographic printing plate precursor of Comparative Example 2 did not exert the preferable characteristics of the specific novolak resin and was inferior in printing durability and chemical resistance though being equal in sensitivity, in comparison with Example 6 having an image recording layer in a layered structure and using absolutely the same specific novolak resin in the image recording layer. Based on such findings, it was confirmed that when a layered structure in which a lower layer is provided between an image recording layer and a support is used, the excellent effects of the present invention of superior development latitude and sensitivity and improved printing durability and chemical resistance are exerted.

According to the invention, as shown above, a heat mode-compatible positive planographic printing plate precursor can be provided, in which generation of a residual film in development is suppressed to thereby enable formation of an image excellent in contrast, and which has printing durability, chemical resistance, and excellent sensitivity.

What is claimed is:

1. A positive planographic printing plate precursor comprising a hydrophilic support, and a lower layer and an image recording layer disposed on the hydrophilic support, wherein:
the lower layer includes a water-insoluble and alkali-soluble resin, and
the image recording layer includes a novolak type phenolic resin containing phenol as a structural unit thereof and a light-to-heat conversion agent, and exhibits increased solubility in an alkaline aqueous solution when exposed to an infrared laser.

2. A planographic printing plate precursor according to claim 1, wherein the novolak type phenolic resin contains phenol as a structural unit thereof in a range of from 20 to 90% by mole.

3. A planographic printing plate precursor according to claim 1, wherein the novolak type phenolic resin is a resin obtained by condensing of phenol and a substituted phenol represented by the following general formula (I) with an aldehyde: 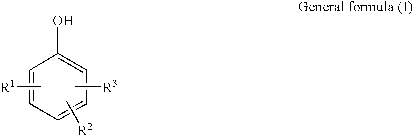
wherein R¹ and R² each independently represent a hydrogen atom, an alkyl group or a halogen atom; R³ represents an alkyl group or cycloalkyl group having 3 to 6 carbon atoms.

4. A planographic printing plate precursor according to claim 3, wherein a phenol content in monomers constituting the resin obtained by condensing of phenol and a substituted phenol represented by general formula (I) with an aldehyde is in a range of from 21 to 90% by mole.

5. A planographic printing plate precursor according to claim 1, wherein the novolak type phenolic resin is a resin obtained by condensing of phenol and at least one of cresol and xylenol with an aldehyde.

6. A planographic printing plate precursor according to claim 5, wherein a phenol content in monomers constituting the resin obtained by condensing of phenol and at least one of cresol and xylenol with an aldehyde is in a range of from 21 to 90% by mole.

7. A planographic printing plate precursor according to claim 5, wherein m-cresol content in monomers constituting the resin obtained by condensing of phenol and at least one of cresol and xylenol with an aldehyde is 10% by mole or more.

8. A planographic printing plate precursor according to claim 1, wherein the image recording layer contains a novolak type phenolic resin other than the novolak type phenolic resin containing phenol as a structural unit thereof in an amount of from 5 to 50% by weight based on a total solid content of all the phenolic type novolak resins.

9. A planographic printing plate precursor according to claim 1, wherein the image recording layer contains a water-insoluble and alkali-soluble resin other than the novolak type phenolic resins selected from the group consisting of a polyamide resin, an epoxy resin, an acetal rein, an acrylic resin, a methacrylic resin, a styrene based resin and a urethane resin.

10. A planographic printing plate precursor according to claim 1, wherein the image recording layer contains a onium salt.

11 A planographic printing plate precursor according to claim 1, wherein the water-insoluble and alkali-soluble resin included in the lower layer is selected from the group consisting of a polyamide resin, an epoxy resin, an acetal rein, an acrylic resin, a methacrylic resin, a styrene based resin and a urethane resin.

12 A planographic printing plate precursor according to claim 1, wherein the image recording layer includes the novolak type phenolic resin and the lower layer includes an acrylic resin.

13 A planographic printing plate precursor according to claim 1, wherein the lower layer includes a light-to-heat conversion agent.
